(19) United States
(12) Patent Application Publication
(10) Pub. No.: US 2025/0357431 A1
(43) Pub. Date: Nov. 20, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Kuo-Ming WU, Tainan City (TW); Ru-Liang LEE, Hsinchu (TW); Sheng-Chau CHEN, Tainan City (TW)

(21) Appl. No.: 19/288,187

(22) Filed: Aug. 1, 2025

Related U.S. Application Data
(63) Continuation of application No. 18/616,674, filed on Mar. 26, 2024.
(60) Provisional application No. 63/589,141, filed on Oct. 10, 2023.

(51) Int. Cl. H01L 25/065; H01L 23/00; H01L 23/552; H01L 25/00

(52) U.S. Cl. CPC H01L 25/0657; H01L 23/552; H01L 24/08; H01L 24/80; H01L 25/50; H01L 2224/08145; H01L 2224/80125; H01L 2224/80895; H01L 2224/80896; H01L 2225/06537; H01L 2924/3025

(57) ABSTRACT

A semiconductor device is formed by bonding a first semiconductor die and a second semiconductor die at bonding pads in the first semiconductor die with bonding vias in the second semiconductor die, and by bonding dielectric layers in the first semiconductor die and in the second semiconductor die. Omitting bonding pads from the second semiconductor device, and instead using the bonding vias to bond the first and second semiconductor dies, provides a greater amount of spacing between the bonding vias of the second semiconductor die in that the bonding vias have lesser widths than bonding pads. This enables a greater amount of dielectric material of the dielectric layers of the second semiconductor device to be placed between the bonding vias without (or with minimally) increasing the lateral size of the second semiconductor die.

### CROSS-REFERENCE TO RELATED APPLICATION

This application is a continuation of U.S. patent application Ser. No. 18/616,674, filed Mar. 26, 2024, which claims priority to U.S. Provisional Patent Application No. 63/589,141, filed on Oct. 10, 2023. The disclosures of the prior applications are considered part of and are incorporated by reference into this patent application.

### BACKGROUND

Bonding in the semiconductor industry is a technique that may be used to form stacked semiconductor devices and three-dimensional integrated circuits. Some examples of bonding include wafer-to-wafer bonding, die-to-wafer bonding, and die-to-die bonding, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2A-2C are diagrams of examples of semiconductor devices described herein.

FIGS. 3A-3J are diagrams of an example implementation of forming a semiconductor die described herein.

FIGS. 4A-4F are diagrams of an example implementation of forming a semiconductor die described herein.

FIGS. 5A and 5B are diagrams of an example implementation of forming a semiconductor device described herein.

FIGS. 6A-6C are diagrams of an example implementation of a bonding via of a semiconductor die and a bonding pad of a semiconductor die described herein.

FIGS. 7A-7C are diagrams of an example implementation of a bonding via of a semiconductor die and a bonding pad of a semiconductor die described herein.

FIGS. 8A-8E are diagrams of an example implementation of a bonding via of a semiconductor die and a bonding pad of a semiconductor die described herein.

FIGS. 9A-9C are diagrams of an example implementation of a bonding via of a semiconductor die and a bonding pad of a semiconductor die described herein.

FIGS. 10A-10C are diagrams of an example implementation of a bonding via of a semiconductor die and a bonding pad of a semiconductor die described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Bonding pads and bonding vias are widely used for bonding semiconductor dies. Bonding of a first semiconductor die and a second semiconductor die may be achieved by bonding the bonding pads on the first semiconductor die with the bonding pads on the second semiconductor die to form metal-to-metal bonds, and by bonding dielectric layers surrounding the bonding pads on the first semiconductor die and on the second semiconductor die to form dielectric-to-dielectric bonds.

As semiconductor processing nodes advance, the spacing between adjacent bonding pads on a semiconductor die may be decreased. In some cases, the reduced spacing between adjacent bonding pads on a semiconductor die may cause unwanted and/or undesirable electrical effects, such as electrical coupling between the adjacent bonding pads. This electrical coupling can lead to increased parasitic capacitance in the semiconductor die and/or another type of performance degradation in the semiconductor die.

In some implementations described herein, a semiconductor device is formed by bonding a first semiconductor die and a second semiconductor die at bonding pads in the first semiconductor die with bonding vias in the second semiconductor die, and by bonding dielectric layers in the first semiconductor die and in the second semiconductor die. The first semiconductor die may include a shielding grid around the bonding pads of the first semiconductor die. The shielding grid provides electrical isolation for the bonding pads of the first semiconductor die, which causes electrical coupling between the bonding pads of the first semiconductor die to be less than if no shielding grid were included.

The bonding vias of the second semiconductor die may have sizes and/or shapes that are different from the sizes and/or shapes of the bonding pads of the first semiconductor die. For example, the bonding vias of the second semiconductor die may have a width that is less than the width of the bonding pads of the first semiconductor die. Omitting bonding pads from the second semiconductor device, and instead using the bonding vias to bond the first and second semiconductor dies, provides a greater amount of spacing between the bonding vias of the second semiconductor die in that the bonding vias have lesser widths than bonding pads. This enables a greater amount of dielectric material of the dielectric layers of the second semiconductor device to be placed between the bonding vias without (or with minimally) increasing the lateral size of the second semiconductor die. The increased spacing between the bonding vias of the second semiconductor die reduces electrical coupling between the bonding vias of the second semiconductor die without the use of another shielding grid in the second semiconductor die. Thus, the increased spacing between the bonding vias of the second semiconductor die enables a less complex manufacturing process to be used to achieve the reduced electrical coupling between the bonding vias of the second semiconductor die.

Additionally and/or alternatively, the different sizes of the bonding pads of the first semiconductor die and the bonding vias of the second semiconductor die provide a greater flexibility and a larger process window for aligning the bonding pads of the first semiconductor die and the bonding vias of the second semiconductor die for bonding. This may decrease the rate and/or likelihood of defect formation for bonding semiconductor dies and/or may increase bonding yield for bonding semiconductor dies.

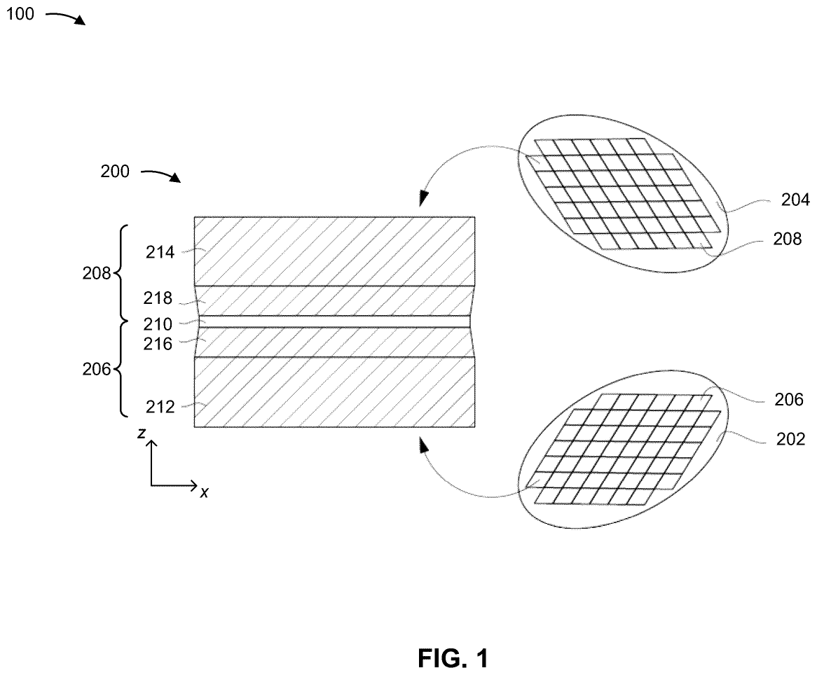

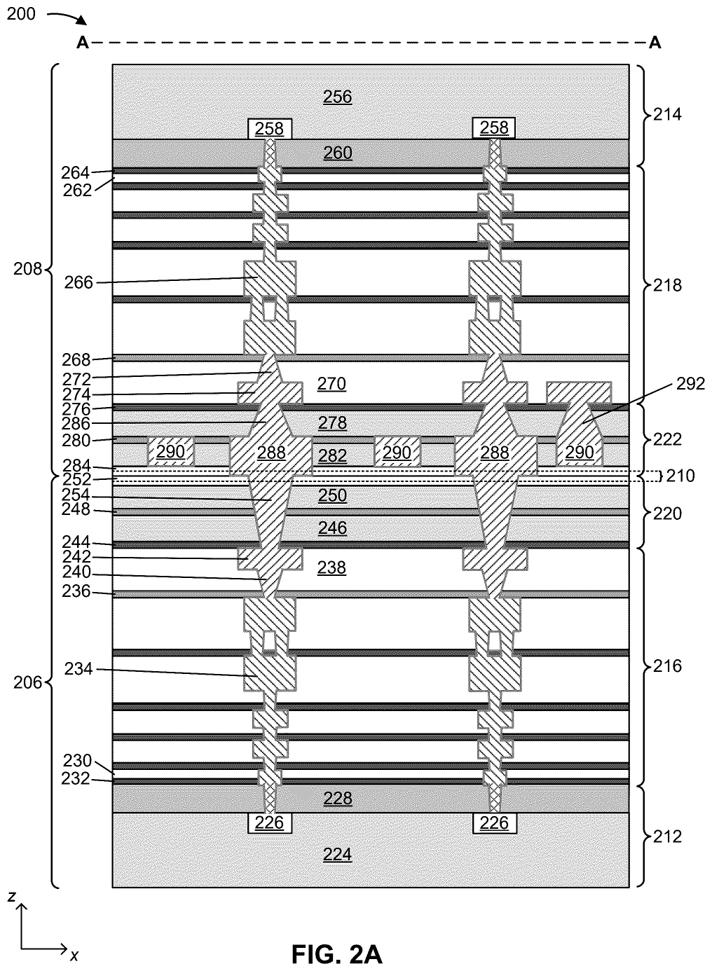

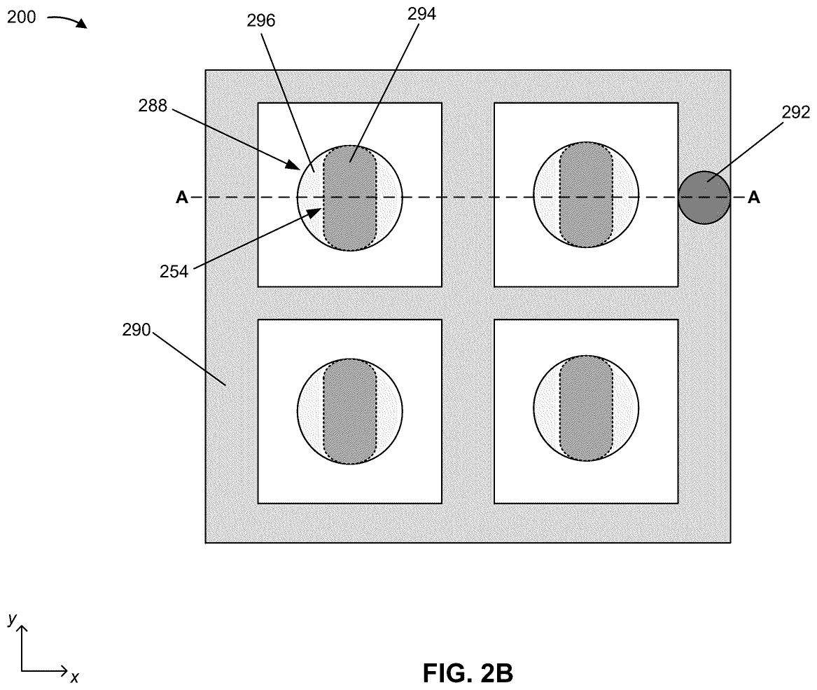

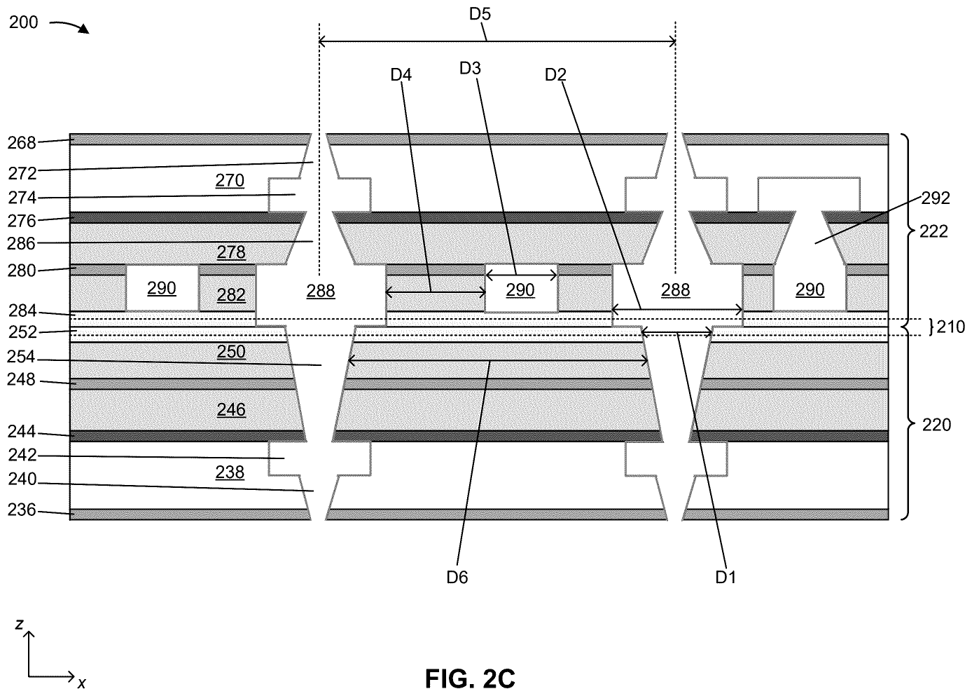

FIGS. 1 and 2A-2C are diagrams of examples of semiconductor devices 200 described herein. FIG. 1, illustrates an example implementation of forming a semiconductor device 200 by bonding a semiconductor wafer 202 and a semiconductor wafer 204. For example, a bonding tool may be used to perform a bonding operation to bond the semiconductor wafer 202 and the semiconductor wafer 204 by forming metal-to-metal bonds and/or dielectric-to-dielectric bonds between the semiconductor wafer 202 and the semiconductor wafer 204. In the bonding operation, semiconductor dies 206 on the semiconductor wafer 202 are bonded with associated semiconductor dies 208 on the semiconductor wafer 204 to form semiconductor devices 200 (e.g., stacked semiconductor devices). The semiconductor devices 200 are then diced and packaged. Other processing steps may be performed to form the semiconductor devices 200.

As shown in FIG. 1, the semiconductor die 206 and the semiconductor die 208 may be bonded at a bonding interface 210 such that the semiconductor die 206 and the semiconductor die 208 are stacked or vertically arranged in a z-direction in the semiconductor device 200. The semiconductor die 206 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 206 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 208 may include the same type of semiconductor die as the semiconductor die 206, or may include a different type of semiconductor die.

As further shown in FIG. 1, the semiconductor die 206 may include a device layer 212, and the semiconductor die 208 may include a device layer 214. The semiconductor die 206 may include an interconnect structure 216 above the device layer 212. The semiconductor die 208 may include an interconnect structure 218 below the device layer 214. The bonding interface 210 may be located between the interconnect structures 216 and 218.

FIG. 2A illustrates a cross-sectional view of the semiconductor device 200 in which the details of the device layers 212 and 214, and the details of the interconnect structures 216 and 218 are shown. FIG. 2A further illustrates details of a bonding structure 220 of the semiconductor die 206 and a bonding structure 222 of the semiconductor die 208. The bonding structure 220 may be included above the interconnect structure 216 of the semiconductor die 206, and the bonding structure 222 may be included below the interconnect structure 218 of the semiconductor die 208. The bonding interface 210 may be located between the bonding structure 220 and the bonding structure 222.

As shown in FIG. 2A, the device layer 212 of the semiconductor die 206 includes a substrate 224. The substrate 224 corresponds to a portion of the semiconductor wafer 202 on which the semiconductor die 206 is formed. The substrate 224 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 224 may extend in an x-direction and/or in a y-direction in the semiconductor die 206.

The semiconductor die 206 includes integrated circuit devices 226 in the substrate 224 and/or on the substrate. The integrated circuit devices 226 may include active device(s), passive device(s), and/or another type of integrated circuit devices. Examples of active devices include transistors (e.g., planar transistors, fin field effect transistors (finFETs), gate all around (GAA) transistors), pixel sensors, modulators, photodetectors, transceivers, and/or transmitters, among other examples. Examples of passive devices include capacitors, resistors, and/or inductors, among other examples.

A dielectric layer 228 is included over the substrate 224. The dielectric layer 228 includes an interlayer dielectric (ILD) layer, an etch stop layer (ESL), and/or another type of dielectric layer. The dielectric layer 228 includes dielectric material(s) that enable various portions of the substrate 224 and/or the integrated circuit devices 226 to be selectively etched or protected from etching, and/or to electrically isolate the integrated circuit devices 226 in the device layer 212. The dielectric layer 228 includes a silicon nitride (SiₓN_{y}), an oxide (e.g., a silicon oxide (SiOₓ) and/or another oxide material), and/or another type of dielectric material. The dielectric layer 228 may extend in the x-direction and/or in the y-direction in the semiconductor die 206.

An interconnect structure 216 of the semiconductor die 206 is included above the substrate 224 and above the integrated circuit devices 226. In some implementations, one or more integrated circuit devices 226 are included in the interconnect structure 216 (e.g., a memory device, a resistor, a capacitor, a radio frequency (RF) switch, an optical modulator, a waveguide). The interconnect structure 216 includes a plurality of dielectric layers that are arranged in a direction (e.g., the z-direction) that is approximately perpendicular to the substrate 224. The dielectric layers may include ILD layers 230 and ESLs 232 that are arranged in an alternating manner in the z-direction. The ILD layers 230 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, an ILD layer 230 includes an extreme low dielectric constant (ELK) dielectric material having a dielectric constant that is less than approximately 2.5. The ESLs 232 may each include a silicon nitride (SiₓN_{y}), silicon carbide (SiC), silicon oxynitride (SiON), and/or another suitable dielectric material. In some implementations, an ILD layer 230 and an ESL 232 include different dielectric materials to provide etch selectivity to enable various structures to be formed in the interconnect structure 216. The ILD layers 230 and the ESLs 232 may extend in the x-direction and/or in the y-direction in the semiconductor die 206.

The interconnect structure 216 includes a plurality of metallization layers 234. The metallization layers 234 are electrically coupled and/or physically coupled with one or more of the integrated circuit devices 226 in the device layer 212 and/or in the interconnect structure 216. The metallization layers 234 correspond to circuitry that enables signals and/or power to be provided to and/or from the integrated circuit devices 226. The metallization layers 234 each include vias, trenches, contacts, plugs, interconnects, and/or other types of conductive structures. The metallization layers 234 each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 234 of the interconnect structure 216 may be arranged in in a vertical manner (e.g., in the z-direction). In other words, a plurality of stacked metallization layers 234 extend between the device layer 212 and the bonding structure 220 to facilitate electrical signals and/or power to be routed between the device layer 212 and the semiconductor die 208. The plurality of stacked metallization layers 234 may be referred to as M-layers. For example, a metal-0 (M0) layer may located at the bottom of the interconnect structure 216 and may be directly coupled with the device layer 212 (e.g., with the contacts or interconnects of the integrated circuit devices 226 in the device layer 212), a metal-1 layer (M1) layer may be located above the M0 layer in the interconnect structure 216, a metal-2 layer (M2) layer may be located above the M1 layer, and so on. In some implementations, the interconnect structure 216 includes nine (9) stacked metallization layers 234 (e.g., M0-M8). In some implementations, the interconnect structure 216 includes another quantity of stacked metallization layers 234.

As further shown in FIG. 2A, the interconnect structure 216 may include an ESL 236 over and/or on the topmost ILD layer 230, and a dielectric layer 238 over and/or on the ESL 236. The ESL 236 may include a silicon nitride (SiₓN_{y} such as Si₃N₄), a silicon oxynitride (SiON), a silicon carbon nitride (SiCN), a silicon oxycarbonitride (SiOCN), and/or another nitride-containing dielectric material. The dielectric layer 238 may include one or more ELK dielectric materials such as include carbon doped silicon oxide (C—SiOₓ), amorphous fluorinated carbon (a-CₓF_{y}), parylene, bis-benzocyclobutenes (BCB), polytetrafluoroethylene (PTFE), and/or a silicon oxycarbide (SiOC) polymer. In some implementations, the ELK dielectric material(s) for the dielectric layer 238 include porous hydrogen silsesquioxane (HSQ), porous methyl silsesquioxane (MSQ), porous polyarylether (PAE), and/or porous silicon oxide (SiOₓ), among other examples. Additionally and/or alternatively, the dielectric layer 238 may include silicon oxide (SiOₓ such as SiO₂), USG, BSG, and/or another suitable dielectric material.

Metal interconnects 240 are included in and/or extend through the ESL 236 and the dielectric layer 238. The metal interconnects 240 are electrically coupled and/or physically coupled with one or more metallization layers 234 in the interconnect structure 216. Metal layers 242 are electrically coupled and/or physically coupled with the metal interconnects 240. The metal layers 242 are also included in the dielectric layer 238.

The bonding structure 220 includes a plurality of dielectric layers 244-250 that are located over and/or on the dielectric layer 238 and/or over and/or on the metal layers 242. The dielectric layer 244 may be included over and/or on the dielectric layer 238, the dielectric layer 246 may be included over and/or on the dielectric layer 244, the dielectric layer 248 may be included over and/or on the dielectric layer 246, and the dielectric layer 250 may be included over and/or on the dielectric layer 248. A bonding dielectric layer 252 is included in the bonding structure 220 over and/or on the dielectric layer 250.

The dielectric layers 244 and 248 may be included in the bonding structure 220 as ESLs. The dielectric layers 244 and 248 may each include a carbon-containing dielectric material such as silicon carbide (SiC). Additionally and/or alternatively, the dielectric layer 244 and/or the dielectric layer 248 may include another dielectric material. The dielectric layer 246 may include a high density plasma (HDP) dielectric material and/or another suitable dielectric material. The dielectric layer 250 may include a nitride-containing dielectric material such as a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The bonding dielectric layer 252 may include a silicon oxynitride (SiON) and/or another suitable bonding dielectric material.

Bonding vias 254 extend through and/or are included in the dielectric layers 244-250 and the bonding dielectric layer 252. The bonding vias 254 are electrically coupled and/or physically coupled with the metal layers 242. The bonding vias 254 each includes a via, an interconnect, a conductive column, a plug, and/or another type of elongated conductive structure. The bonding vias 254 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

The z-direction thickness of the bonding vias 254 may be greater than the x-direction and/or y-direction width of the bonding vias 254. For example, z-direction thickness of the bonding vias 254 may be at least two times greater than the x-direction and/or y-direction width of the bonding vias 254.

As further shown in FIG. 2A, the device layer 214 of the semiconductor die 208 includes a substrate 256. The substrate 256 corresponds to a portion of the semiconductor wafer 204 on which the semiconductor die 208 is formed. The substrate 256 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 256 may extend in the x-direction and/or in the y-direction in the semiconductor die 208.

Semiconductor devices 258 are included in and/or under the substrate 256 in the device layer 214 of the semiconductor die 208. The semiconductor devices 258 include transistors (e.g., planar transistors, finFETs, GAA transistors), pixel sensors, capacitors, resistors, inductors, photodetectors, transceivers, transmitters, receives, optical circuits, and/or other types of semiconductor devices.

A dielectric layer 260 is included under the substrate 256. The dielectric layer 260 includes an ILD layer, an ESL, and/or another type of dielectric layer. The dielectric layer 260 includes dielectric material(s) that enable various portions of the substrate 256 and/or the semiconductor devices 258 to be selectively etched or protected from etching, and/or to electrically isolate the semiconductor devices 258 in the device layer 214. The dielectric layer 260 includes a silicon nitride (SiₓN_{y}), an oxide (e.g., a silicon oxide (SiOₓ) and/or another oxide material), and/or another type of dielectric material.

An interconnect structure 218 of the semiconductor die 208 is included below and/or under the substrate 256 and below the semiconductor devices 258. In some implementations, one or more semiconductor devices 258 are included in the interconnect structure 218 (e.g., a memory device, a resistor, a capacitor, an RF switch, an optical modulator, a waveguide). The interconnect structure 218 includes a plurality of dielectric layers that are arranged in a direction that is approximately perpendicular to the substrate 256. The dielectric layers may include ILD layers 262 and ESLs 264 that are arranged in an alternating manner in the z-direction in the semiconductor die 208. The ILD layers 262 may each include an oxide (e.g., a silicon oxide (SiOₓ) and/or another oxide material), a USG, a BSG, an FSG, and/or another suitable dielectric material. In some implementations, an ILD layer 262 includes an ELK dielectric material having a dielectric constant that is less than approximately 2.5. The ESLs 264 may each include a silicon nitride (SiₓN_{y}), silicon carbide (SiC), silicon oxynitride (SiON), and/or another suitable dielectric material. In some implementations, an ILD layer 262 and an ESL 264 include different dielectric materials to provide etch selectivity to enable various structures to be formed in the interconnect structure 218. The ILD layers 262 and ESLs 264 may extend in the x-direction and/or in the y-direction in the semiconductor die 208.

The interconnect structure 218 includes a plurality of metallization layers 266. The metallization layers 266 are electrically coupled and/or physically coupled with one or more of the semiconductor devices 258 in the device layer 214 and/or in the interconnect structure 218. The metallization layers 266 correspond to circuitry that enables signals and/or power to be provided to and/or from the semiconductor devices 258. The metallization layers 266 each includes vias, trenches, contacts, plugs, interconnects, and/or other types of conductive structures. The metallization layers 266 each includes one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 266 of the interconnect structure 218 may be arranged in in a vertical manner in the z-direction in the semiconductor die 208. In other words, a plurality of stacked metallization layers 266 extend between the device layer 214 and the bonding structure 222 to facilitate electrical signals and/or power to be routed between the device layer 214 and the semiconductor die 206. The plurality of stacked metallization layers 266 may be referred to as M-layers. In some implementations, the interconnect structure 218 includes nine (9) stacked metallization layers 266 (e.g., M0-M8). In some implementations, the interconnect structure 218 includes another quantity of stacked metallization layers 266.

As further shown in FIG. 2A, the interconnect structure 218 may include an ESL 268 below and/or under an ILD layer 262, and a dielectric layer 270 below and/or under the ESL 268. The ESL 268 may include a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The dielectric layer 270 may include one or more ELK dielectric materials such as carbon doped silicon oxide (c-SiOₓ), amorphous fluorinated carbon (a-CₓF_{y}), parylene, BCB, PTFE, and/or a silicon oxycarbide (SiOC) polymer. Additionally and/or alternatively, the dielectric layer 270 may include porous HSQ, porous MSQ, porous PAE, silicon oxide (SiOₓ), USG, and/or BSG, among other examples.

Metal interconnects 272 may be included in and/or may extend through the ESL 268 and the dielectric layer 270. The metal interconnects 272 are electrically coupled and/or physically coupled with one or more metallization layers 266. Metal layers 274 are electrically coupled and/or physically coupled with the metal interconnects 272. The metal layers 274 are also included in the dielectric layer 270.

The bonding structure 222 includes a plurality of dielectric layers, such as dielectric layers 276-282 under the interconnect structure 218, and a bonding dielectric layer 284 under the dielectric layers 276-282. The dielectric layer 276 is included below and/or under the dielectric layer 270, the dielectric layer 278 is included below and/or under the dielectric layer 276, the dielectric layer 280 is included below and/or under the dielectric layer 278, and the dielectric layer 282 is included below and/or under the dielectric layer 280.

The dielectric layers 276 and 280 may be included in the bonding structure 222 as ESLs. The dielectric layers 276 and 280 may each include a carbon-containing dielectric material such as silicon carbide (SiC), a nitride-containing material such as silicon carbon nitride (SiCN), and/or another suitable ESL material. The dielectric layers 278 and 282 may each include an HDP dielectric material and/or another suitable dielectric material. The bonding dielectric layer 284 may include a silicon oxynitride (SiON) and/or another suitable bonding dielectric material.

Bonding vias 286 extend through and/or are included in the dielectric layers 276 and 278. The bonding vias 286 are electrically coupled and/or physically coupled with the metal layers 274. The bonding vias 286 each includes a via, an interconnect, a conductive column, a plug, and/or another type of conductive structure. The bonding vias 286 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

Bonding pads 288 extend through and/or are included in the dielectric layer 280, the dielectric layer 282, and the bonding dielectric layer 284. The bonding pads 288 are electrically coupled and/or physically coupled with the bonding vias 286. The bonding pads 288 each includes a trench, a pad, a contact, and/or another type of conductive bonding structure. The bonding pads 288 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

At the bonding interface 210, the bonding dielectric layer 252 and the bonding dielectric layer 284 are bonded by a dielectric-to-dielectric bond. The bonding vias 254 of the semiconductor die 206 are bonded with the bonding pads 288 of the semiconductor die 208 by a metal-to-metal bond. The combination of the dielectric-to-dielectric bond and the metal-to-metal bond is sometimes referred to as a “hybrid bond.” FIG. 2A illustrates a frontside-to-frontside bond of the semiconductor dies 206 and 208, where the bonding interface 210 is located between the interconnect structures 216 and 218 that are located above the frontside of the semiconductor dies 206 and 208, respectively. In other implementations, the bonding interface 210 may be located between the backsides of the semiconductor dies 206 and 208, and thus may include a backside-to-backside bond. Alternatively, the bonding interface 210 may be located between a frontside of the semiconductor die 206 and a backside of the semiconductor die 208, or between a frontside of the semiconductor die 208 and a backside of the semiconductor die 206, among other examples.

As further shown in FIG. 2A, a shielding grid 290 may be included between the bonding pads 288 in the bonding structure 222 of the semiconductor die 208. The shielding grid 290 includes a plurality of intersecting trenches of electrically conductive material, such as copper (Cu), tungsten (W), cobalt (Co), ruthenium (Ru), titanium (Ti), aluminum (Al), gold (Au), and/or a combination thereof, among other examples of electrically conductive materials. The shielding grid 290 may be included in the dielectric layers 280 and 282 and therefore may be located above the bonding vias 254 in the semiconductor device 200. The bonding dielectric layer 284 may be included between the shielding grid 290 and the semiconductor die 206. The shielding grid 290 may be physically coupled and/or electrically coupled with a grounding via 292 that electrically connects the shielding grid 290 to the metal layer 274 for electrical grounding. The grounding via 292 includes an electrically conductive material, such as copper (Cu), tungsten (W), cobalt (Co), ruthenium (Ru), titanium (Ti), aluminum (Al), gold (Au), and/or a combination thereof, among other examples of electrically conductive materials.

The shielding grid 290 provides electrical isolation between the bonding pads 288 and reduces electrical coupling between the bonding pads 288 in the semiconductor die 208. Bonding the bonding vias 254 directly with the bonding pads 288, instead of including additional bonding pads in the semiconductor die 206 for bonding with the bonding pads 288, provides increased distance (or increased spacing) between adjacent bonding vias 254 in the semiconductor die 206. The increased distance reduces electrical coupling between the bonding vias 254 in the semiconductor die 206 without including an additional shielding grid in the semiconductor die 206. For example, increased distance may reduce electrical coupling by approximately 4% to approximately 5% or greater between the bonding vias 254 in the semiconductor die 206 than if bonding pads were used to bond the semiconductor die 206 with the bonding pads 288 of the semiconductor die 208. Thus, bonding the bonding vias 254 directly with the bonding pads 288 may reduce the complexity, time, and cost of forming the semiconductor die 206 in that fewer semiconductor processing operations are performed for forming the semiconductor die 206 than if bonding pads and an additional shielding grid were included.

FIG. 2B illustrates a top-down view of the semiconductor device 200, in which the location of the cross-section along the line A-A is shown. As shown in FIG. 2B, the cross-section along the line A-A extends through a plurality of bonding vias 254 of the semiconductor die 206, through a plurality of bonding pads 288 of the semiconductor die 208, through the shielding grid 290 of the semiconductor die 208, and through the grounding via 292 of the semiconductor die 208. The shielding grid 290 surrounds the bonding pads 288 in the x-y plane of the semiconductor die 208.

The bonding vias 254 of the semiconductor die 206 and the bonding pads 288 of the semiconductor die 208 are bonding at bonding surfaces 294 of the bonding vias 254 and bonding surfaces 296 of the bonding pads 288. A size (e.g., the surface area) of a bonding surface 294 in the x-y plane of the semiconductor device 200 is less than a size (e.g., the surface area) of a bonding surface 296 of a bonding pad 288 in the x-y plane. The bonding vias 254 and the bonding pads 288 are bonded such that an entirety of a bonding surface 294 of a bonding via 254 is located within a perimeter of a bonding surface 296 of a bonding pad 288 and is bonded with the bonding surface 296. The bonding surface 294 of the bonding via 254 partially overlaps the bonding surface 296 of the bonding pad 288 because of the lesser size of the bonding surface 294 of the bonding via 254. The bonding vias 254 and the bonding pads 288 are bonded such that less than an entirety of the bonding surface 296 of the bonding pad 288 is located within a perimeter of the bonding surface 294 of a bonding via 254 and is bonded with the bonding surface 294. This occurs because of the greater size of the bonding surface 296. In some implementations, the bonding surface 296 of the bonding pad 288 fully overlaps the bonding surface 294 of the bonding via 254 because of the greater size of the bonding surface 296 of the bonding pad 288. However, in other implementations, some misalignment occurs in bonding the semiconductor die 206 and the semiconductor die 208, and the bonding surface 296 of the bonding pad 288 may partially overlap the bonding surface 294 of the bonding via 254.

The lesser size of the bonding surfaces 294 of the bonding vias 254 provides greater flexibility in achieving a satisfactory overlay (e.g., x-y direction alignment) between the bonding via 254 and the bonding pad 288 such that sufficient bonding quality may be achieved. This provides a greater flexibility and a larger process window for aligning the bonding vias 254 of the semiconductor die 206 and the bonding pads 288 of the semiconductor die 208 for bonding, which may decrease the rate and/or likelihood of defect formation for bonding semiconductor dies on the semiconductor wafers 202 and 204 and/or may increase bonding yield for bonding semiconductor dies on the semiconductor wafers 202 and 204.

FIG. 2C illustrates one or more dimensions of the semiconductor device 200. Additionally and/or alternatively, the one or more dimensions illustrated in FIG. 2C are dimensions of a bonding via 254 and/or of a bonding pad 288. An example dimension D1 includes a cross-sectional width (e.g., an x-direction width, a y-direction width) of a top of a bonding via 254. In some implementations, the dimension D1 is included in a range of approximately 0.1 microns to 0.3 microns. However, other values for the range are within the scope of the present disclosure. Another example dimension D2 includes a cross-sectional width (e.g., an x-direction width, a y-direction width) of a bonding pad 288. In some implementations, the dimension D2 is included in a range of approximately 0.3 microns to 0.5 microns. However, other values for the range are within the scope of the present disclosure.

The cross-sectional width (e.g., in the x-direction and/or in the y-direction) of a bonding pad 288 may be greater than a cross-sectional width (e.g., in the x-direction and/or in the y-direction) of a bonding via 254. This provides greater distance (or greater spacing) between adjacent bonding vias 254 in the semiconductor die 206 relative to the distance or spacing between adjacent bonding pads 288 in the semiconductor die 208. The increased distance reduces electrical coupling between the bonding vias 254 in the semiconductor die 206 without including an additional shielding grid in the semiconductor die 206. In some implementations, a ratio of the dimension D2 to the dimension D1 is greater than approximately 1:1 and up to 5:1 or greater. However, other values for the range are within the scope of the present disclosure.

Another example dimension D3 includes a cross-sectional width (e.g., an x-direction width, a y-direction width) of a section of the shielding grid 290. In some implementations, the dimension D3 is included in a range of approximately 0.1 microns to 0.5 microns. However, other values for the range are within the scope of the present disclosure. Another example dimension D4 includes a distance (e.g., an x-direction distance, a y-direction distance) between a bonding pad 288 and the shielding grid 290. In some implementations, the dimension D4 is included in a range of approximately 0.1 microns to approximately 0.2 microns. If the dimension D4 is less than approximately 0.1 microns, pattern defects may occur when forming the shielding grid 290 and/or the bonding pad 288, and those pattern defects may result in electrical shorting between the bonding pad 288 and the shielding grid 290. If the dimension D4 is greater than approximately 0.2 microns, the bonding pads 288 and the shielding grid 290 may be spaced too far apart to achieve a high density of bonding pads 288 in the semiconductor die 208. If the dimension D4 is included in the range of approximately 0.1 microns to approximately 0.2 microns, a high density of bonding pads 288 may be achieved in the semiconductor die 208 without unduly increasing the likelihood of electrical shorting between the bonding pads 288 and the shielding grid 290. However, other values for the dimension D4, and ranges other than approximately 0.1 microns to approximately 0.2 microns, are within the scope of the present disclosure.

Another example dimension D5 includes a pitch between adjacent bonding pads 288 (e.g., the distance between the centers of the adjacent bonding pads 288). In some implementations, the dimension D5 is included in a range of approximately 0.75 microns to approximately 1 micron. If the dimension D5 is less than approximately 0.75 microns, pattern defects may occur when forming the shielding grid 290 and/or the bonding pad 288 because of insufficient spacing between the bonding pads 288, and those pattern defects may result in electrical shorting between the bonding pad 288 and the shielding grid 290. If the dimension D5 is greater than approximately 1 micron, the bonding pads 288 may be spaced too far apart to achieve a high density of bonding pads 288 in the semiconductor die 208. If the dimension D5 is included in the range of approximately 0.75 microns to approximately 1 micron, a high density of bonding pads 288 may be achieved in the semiconductor die 208 without unduly increasing the likelihood of electrical shorting between the bonding pads 288 and the shielding grid 290. However, other values for the dimension D5, and ranges other than approximately 0.75 microns to approximately 1 micron, are within the scope of the present disclosure.

Another example dimension D6 includes a distance (or spacing) between adjacent bonding vias 254. The dimension D6 is greater than the dimension D4 (e.g., the distance between the shielding grid 290 and the bonding pads 288 is less than the distance between adjacent bonding vias 254) and is greater than the distance between adjacent bonding pads 288. This enables a low amount of electrical coupling between the bonding vias 254 to be achieved while enabling a high density of bonding vias 254 to be included in the semiconductor die 206.

As indicated above, FIGS. 1 and 2A-2C are provided as examples. Other examples may differ from what is described with regard to FIGS. 1 and 2A-2C.

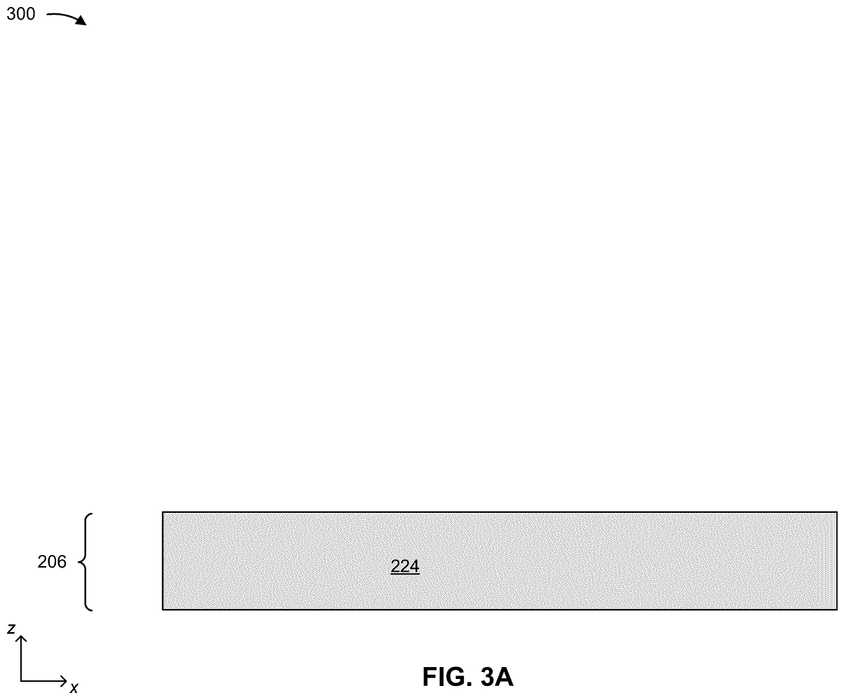

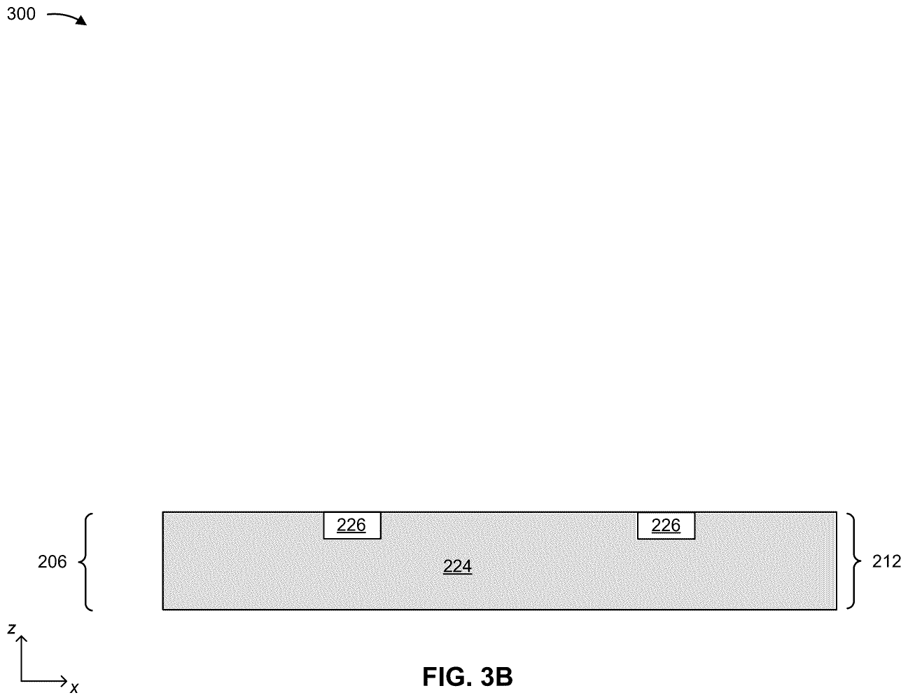

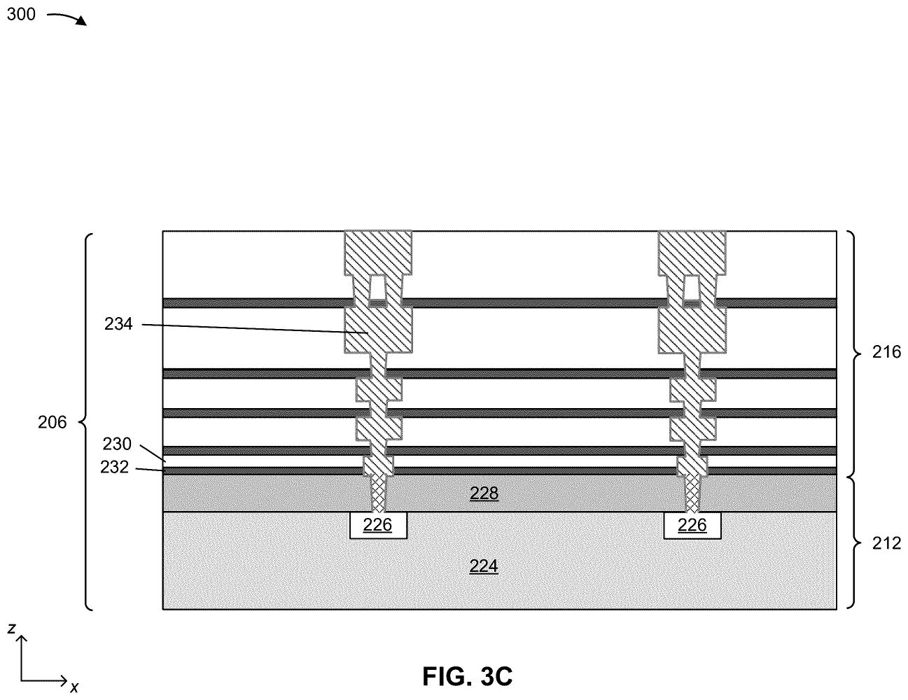

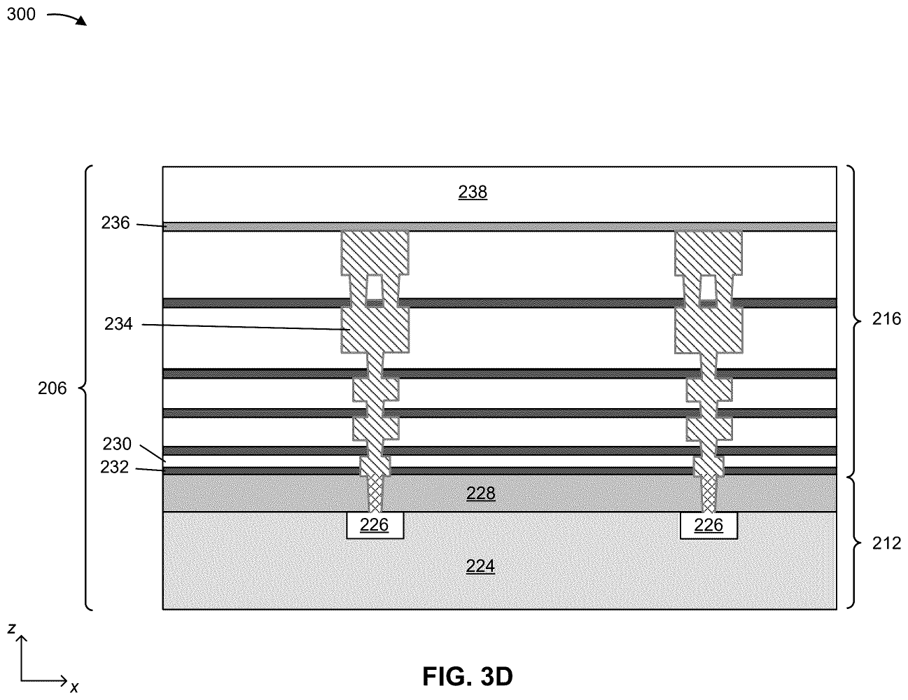

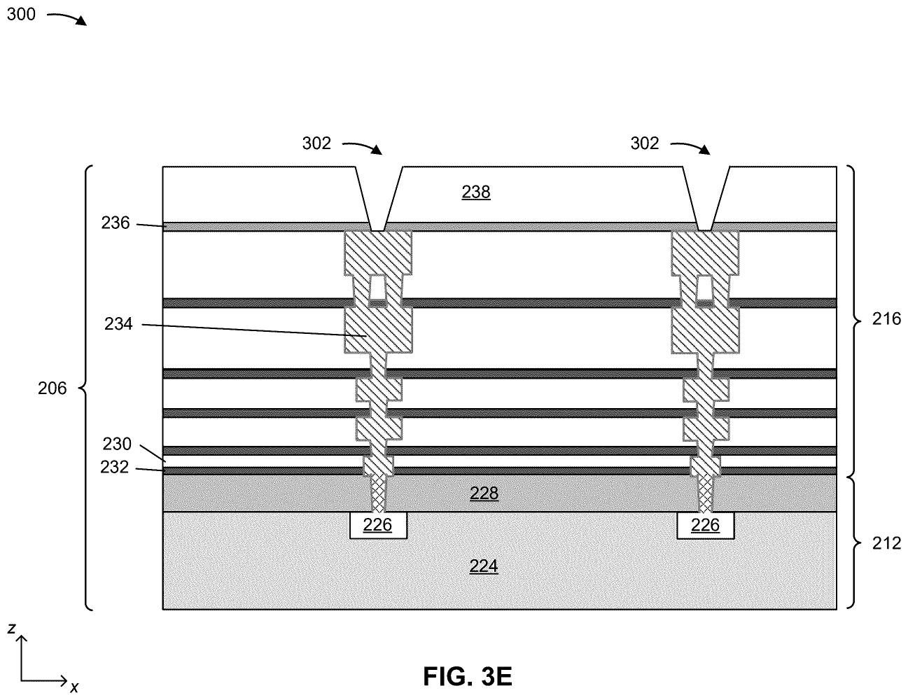

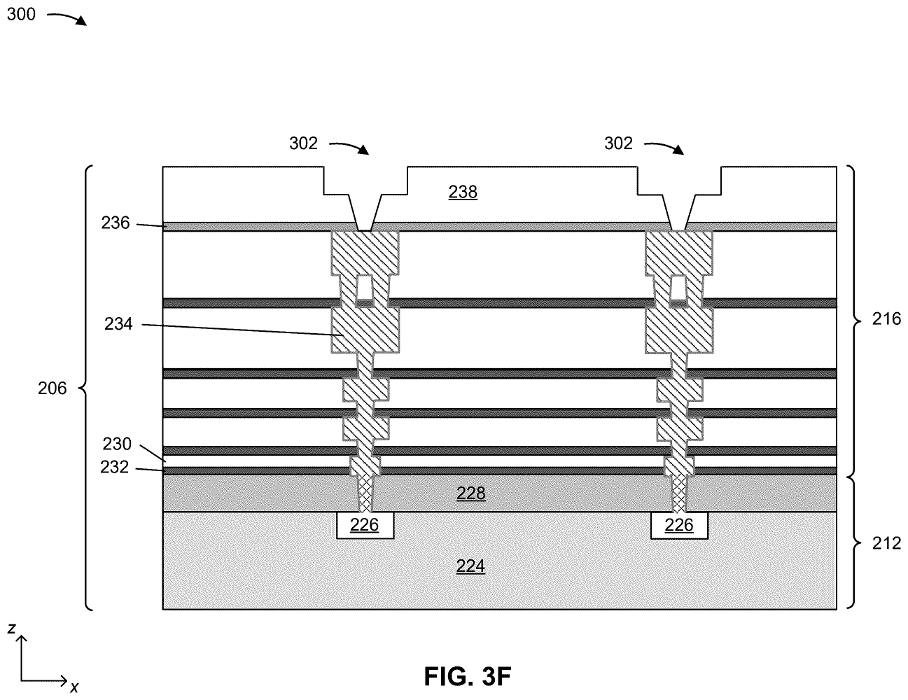

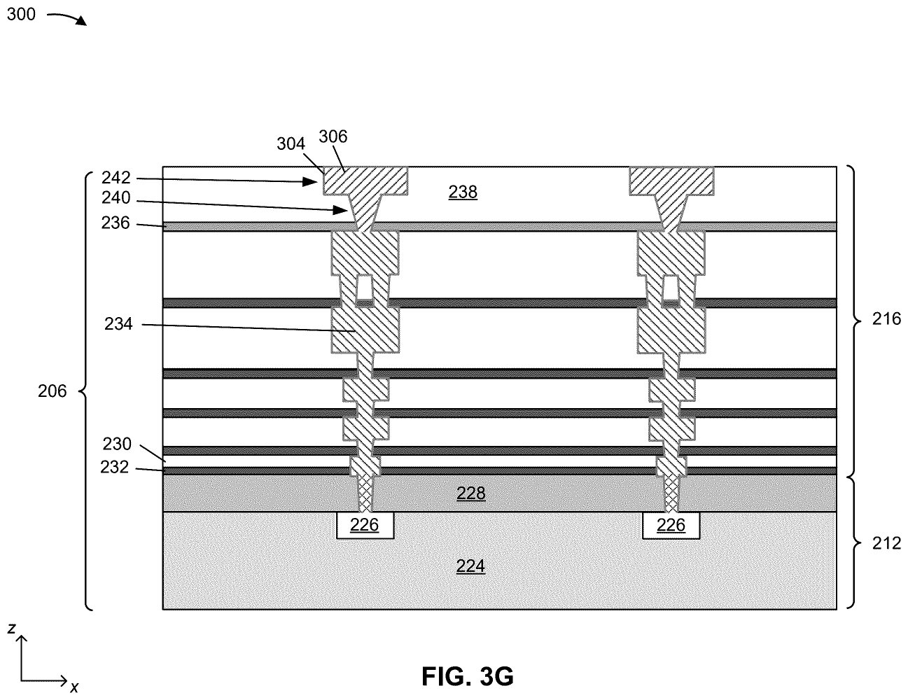

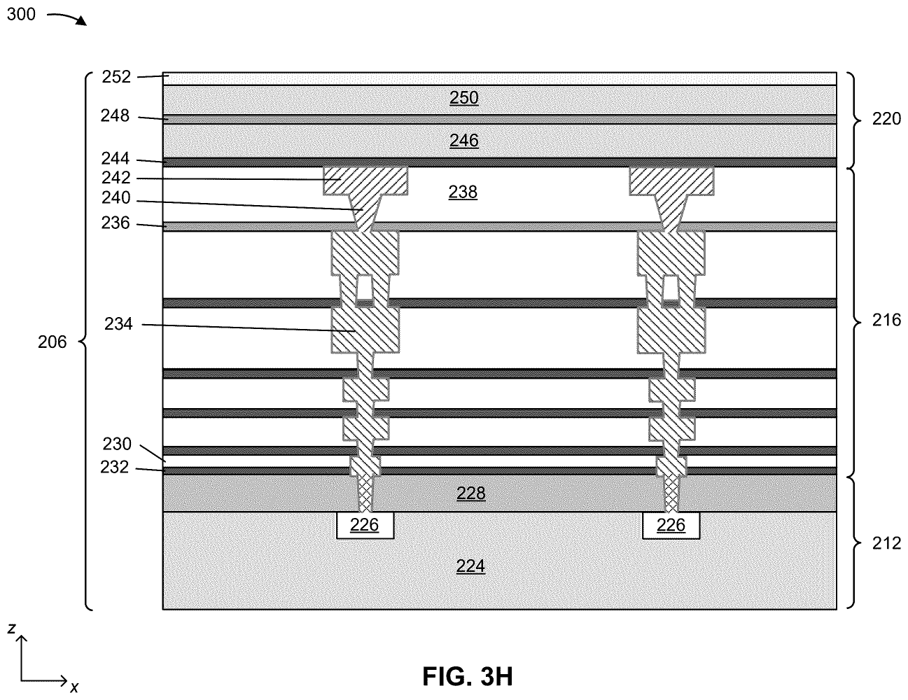

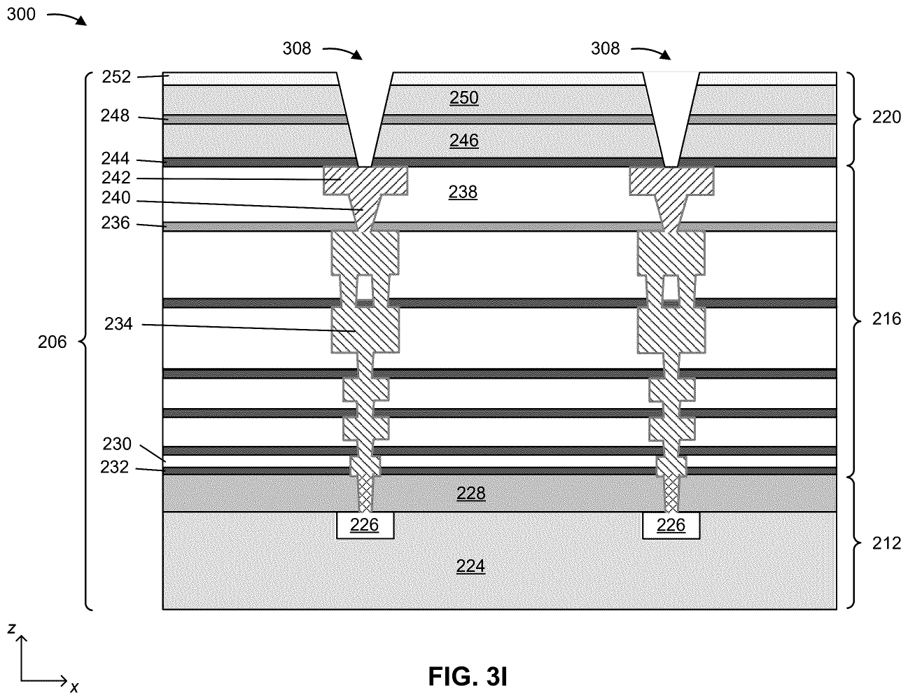

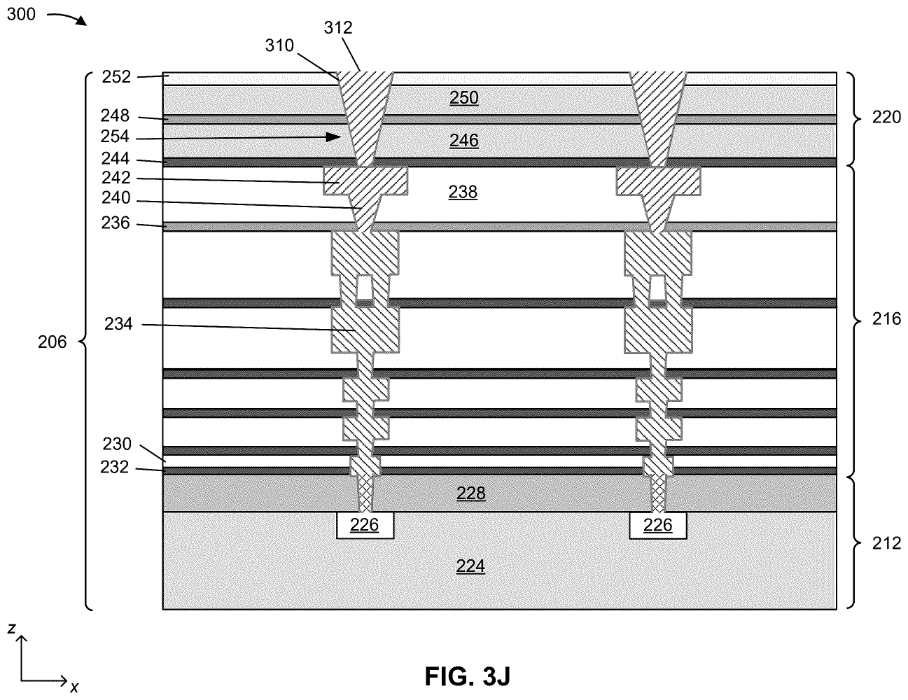

FIGS. 3A-3J are diagrams of an example implementation 300 of forming a semiconductor die 206 described herein. In some implementations, one or more of the semiconductor processing tools may be used to perform one or more of the semiconductor processing operations described in connection with FIGS. 3A-3J.

Turning to FIG. 3A, the substrate 224 may be provided. The substrate 224 may be provided in the form of a semiconductor wafer (e.g., the semiconductor wafer 202) such as a silicon (Si) wafer. The semiconductor die 206 may be formed on the substrate 224 along with a plurality of other semiconductor dies 206.

As shown in FIG. 3B, the integrated circuit devices 226 may be formed in and/or on the substrate 224 in the device layer 212 of the semiconductor die 206. One or more semiconductor processing tools may be used to form one or more portions of the integrated circuit devices 226. For example, a deposition tool may be used to perform various deposition operations to deposit layers of the integrated circuit devices 226, and/or to deposit photoresist layers for etching the substrate 224 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 224 and/or portions of the deposited layers to form the semiconductor devices 226. As another example, a planarization tool may be used to planarize portions of the integrated circuit devices 226. As another example, a plating tool may be used to deposit metal structures and/or layers of the integrated circuit devices 226.

As shown in FIG. 3C, a deposition tool is used to deposit the dielectric layer 228 over and/or on the substrate 224 and over and/or on the integrated circuit devices 226. A deposition tool is also used to deposit alternating layers of ESLs 232 and ILD layers 230 of the interconnect structure 216 of the semiconductor die 206. A deposition tool, an exposure tool, a developer tool, an etch tool, a planarization tool, and/or a plating tool are used to perform various operations to form the metallization layers 234 in the interconnect structure 216 of the semiconductor die 206. The metallization layers 234 may be formed in the ILD layers 230 and/or the ESLs 232, and may be electrically coupled with the integrated circuit devices 226 in the device layer 212. For example, a recess may be formed in an ESL 232 and/or in an ILD layer 230, and a metallization layer 234 may be formed in the recess.

As shown in FIG. 3D, an ESL 236 may be formed over and/or on an ILD layer 230 and over and/or on one or more metallization layers 234. A dielectric layer 238 is formed over and/or on the ESL 236. A deposition tool may be used to deposit the ESL 236 and/or the dielectric layer 238 using a PVD technique, an ALD technique, a CVD technique, an oxidation technique, and/or another suitable deposition technique. In some implementations, a planarization tool may be used to planarize the ESL 236 and/or the dielectric layer 238 after the ESL 236 and/or the dielectric layer 238 are deposited.

As shown in FIGS. 3E and 3F, recesses 302 are formed in and/or through the dielectric layer 238 and the ESL 236. The top surfaces of the topmost metallization layers 234 in the interconnect structure 216 are exposed through the recesses 302. In some implementations, a dual damascene process is used to form the recesses 302. For example, and as shown in FIG. 3E, a via portion of the recesses 302 may be formed in and/or through the dielectric layer 238 and the ESL 236. In particular, the via portion may be formed from a top surface of the dielectric layer 238 through the dielectric layer 238, and through the ESL 236. A deposition tool may be used to form a photoresist layer on the dielectric layer 238. An exposure tool may be used to expose the photoresist layer to a radiation source to pattern the photoresist layer. A developer tool may be used to develop and remove portions of the photoresist layer to expose the pattern. An etch tool may be used to etch the dielectric layer 238 and the ESL 236 to form the via portion of the recesses 302. In some implementations, a photoresist removal tool removes the remaining portions of the photoresist layer (e.g., using a chemical stripper and/or another technique).

A trench portion of the recesses 302 may be formed in the dielectric layer 238 above the via portion. In particular, the trench portion may be formed from the top surface of the dielectric layer 238 and into a portion of the dielectric layer 238. A deposition tool may be used to form a photoresist layer on the dielectric layer 238. An exposure tool may be used to expose the photoresist layer to a radiation source to pattern the photoresist layer. A developer tool may be used to develop and remove portions of the photoresist layer to expose the pattern. An etch tool may be used to etch the dielectric layer 238 to form the trench portion of the recesses 302 in the dielectric layer 238. In some implementations, a photoresist removal tool removes the remaining portions of the photoresist layer (e.g., using a chemical stripper and/or another technique).

FIGS. 3E and 3F illustrate an example via-first dual damascene procedure in which the recesses 302 are formed by forming the via portion before forming the trench portion. In some implementations, a trench-first dual damascene procedure, in which the recesses 302 are formed by forming the trench portion before forming the via portion, may be performed.

As shown in FIG. 3G, the metal interconnects 240 are formed in the via portion of the recesses 302 such that the metal interconnects 240 land on (and are electrically coupled and/or physically coupled with) the topmost metallization layer 234. The metal layers 242 are formed in the trench portion of the recesses 302 on the metal interconnects 240. The metal interconnects 240 and the metal layers 242 include one or more liner layers 304 and a conductive structure 306. The one or more liner layers 304 may include adhesion layers, barrier layers, and/or another type of liners that are conformally deposited on the sidewalls and/or the bottom surfaces of the recesses 302. Examples of materials for the one or more liner layers 304 include tantalum nitride (TaN), titanium nitride (TiN), ruthenium (Ru), cobalt (Co), and/or ruthenium oxide (RuOₓ), among other examples.

A deposition tool may be used to deposit the one or more liner layers 304 using a PVD technique, an ALD technique, a CVD technique, and/or another suitable deposition technique. A deposition tool and/or a plating tool may be used to deposit the metal interconnects 240 and the metal layers 242 using a CVD technique, a PVD technique, an ALD technique, an electroplating technique, and/or another suitable deposition technique. In some implementations, a seed layer is first deposited, and a metal interconnect 240 and/or a metal layer 242 are deposited on the seed layer. In some implementations, a planarization tool is used to planarize the metal layers 242 after the metal layers 242 are deposited.

As shown in FIG. 3H, the dielectric layers 244-250 and the bonding dielectric layer 252 are formed over and/or on the dielectric layer 238. The dielectric layers 244-250 and the bonding dielectric layer 252 are formed over and/or on the metal layers 242. A deposition tool may be used to deposit the dielectric layers 244-250 and/or the bonding dielectric layer 252 using a PVD technique, an ALD technique, a CVD technique, and/or another suitable deposition technique. In some implementations, a planarization tool is used to planarize one or more or more of the dielectric layers 244-250 and/or the bonding dielectric layer 252 after the one or more or more of the dielectric layers 244-250 and/or the bonding dielectric layer 252 are deposited.

As shown in FIG. 3I, recesses 308 are formed in and/or through the dielectric layers 244-250 and the bonding dielectric layer 252. The top surfaces of the metal layers 242 are exposed through the recesses 308. In some implementations, a pattern is used to etch the dielectric layers 244-250 and/or the bonding dielectric layer 252 to form the recesses 308. A deposition tool may be used to form a photoresist layer on the bonding dielectric layer 252. An exposure tool may be used to expose the photoresist layer to a radiation source to pattern the photoresist layer. A developer tool may be used to develop and remove portions of the photoresist layer to expose the pattern. An etch tool may be used to etch the dielectric layers 244-250 and the bonding dielectric layer 252 based on the pattern to form the recesses 308. In some implementations, a photoresist removal tool removes the remaining portions of the photoresist layer (e.g., using a chemical stripper and/or another technique). Additionally and/or alternatively, a hard mask layer is used to form the recesses 308 based on a pattern.

As shown in FIG. 3J, the bonding vias 254 are formed in the recesses 308 such that the bonding vias 254 land on (and are electrically coupled and/or physically coupled with) the metal layers 242. The bonding vias 254 each include one or more liner layers 310 and a conductive structure 312. The one or more liner layers 310 may include adhesion layers, barrier layers, and/or another type of liners that are conformally deposited on the sidewalls and/or the bottom surfaces of the recesses 308. Examples of materials for the one or more liner layers 310 include tantalum nitride (TaN), titanium nitride (TiN), ruthenium (Ru), cobalt (Co), and/or ruthenium oxide (RuOₓ), among other examples.

A deposition tool may be used to deposit the one or more liner layers 310 using a PVD technique, an ALD technique, a CVD technique, and/or another suitable deposition technique. A deposition tool and/or a plating tool may be used to deposit conductive structures 312 of the bonding vias 254 using a CVD technique, a PVD technique, an ALD technique, an electroplating technique, and/or another suitable deposition technique. In some implementations, a seed layer is first deposited, and a bonding via 254 is deposited on the seed layer. In some implementations, a planarization tool is used to planarize the bonding vias 254 after the bonding vias 254 are deposited.

As indicated above, FIGS. 3A-3J are provided as an example. Other examples may differ from what is described with regard to FIGS. 3A-3J.

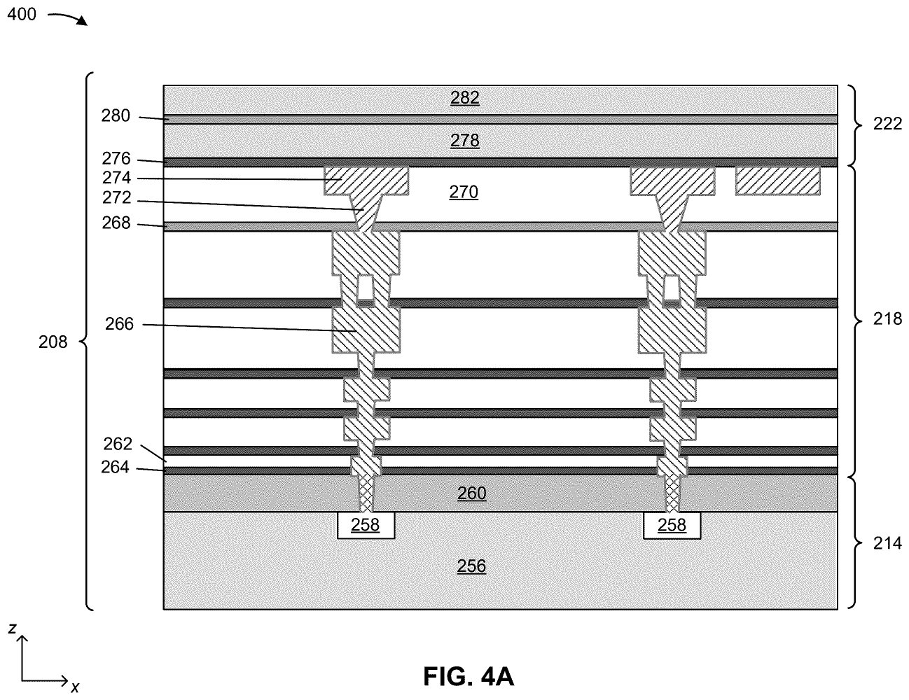

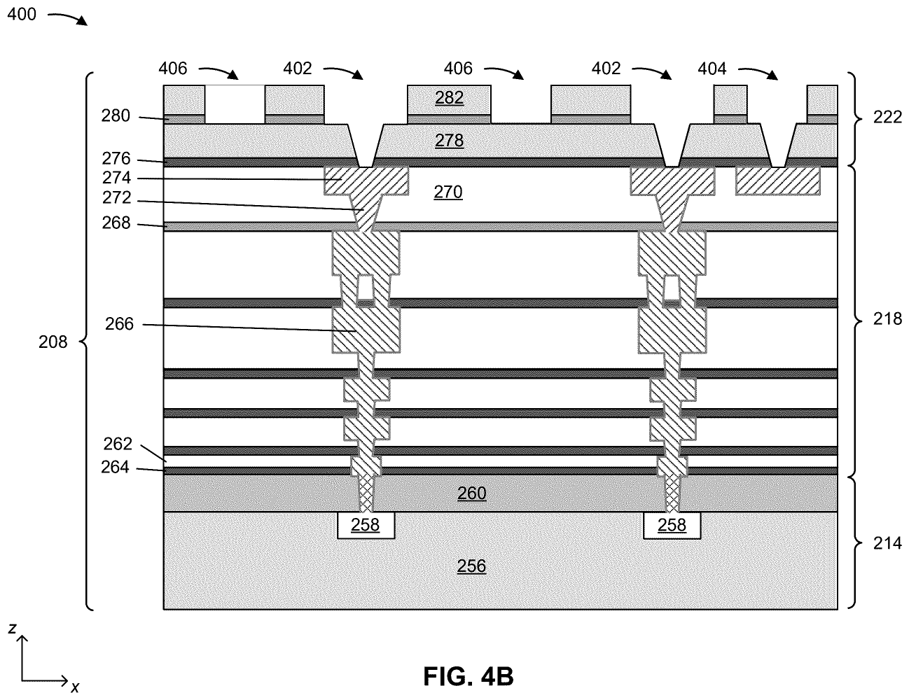

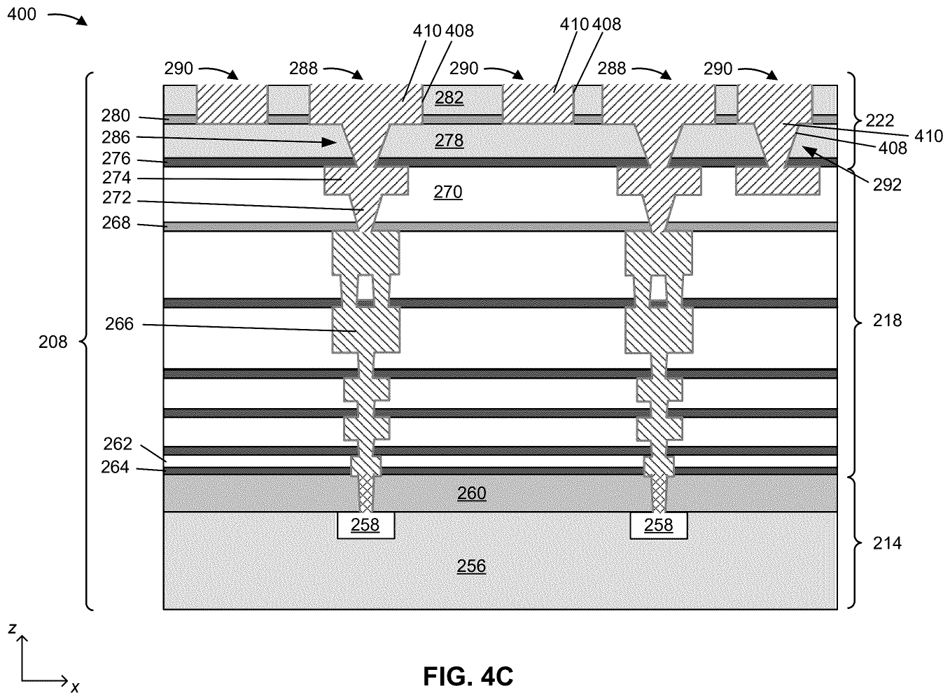

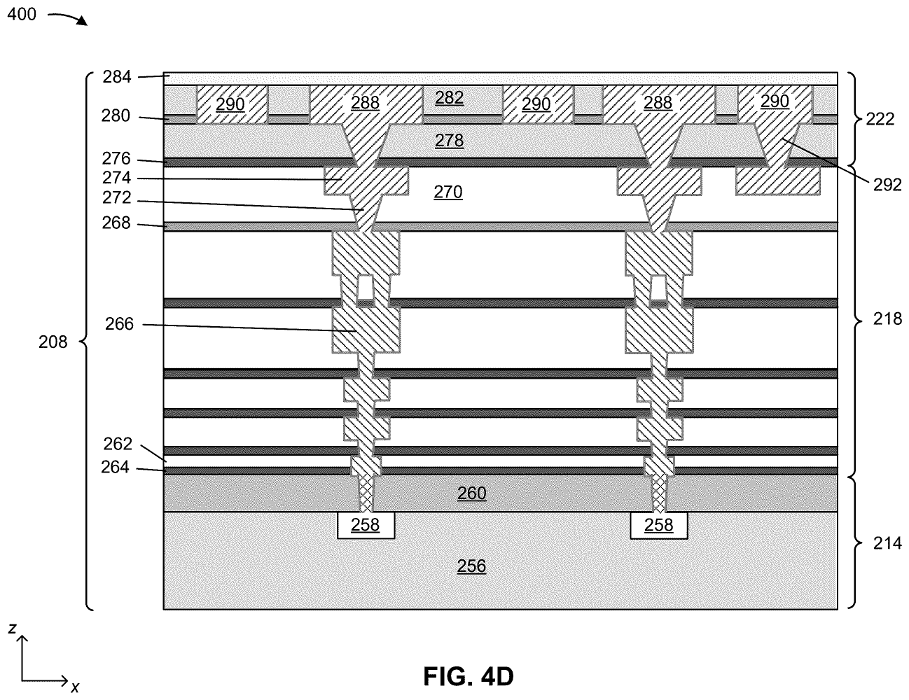

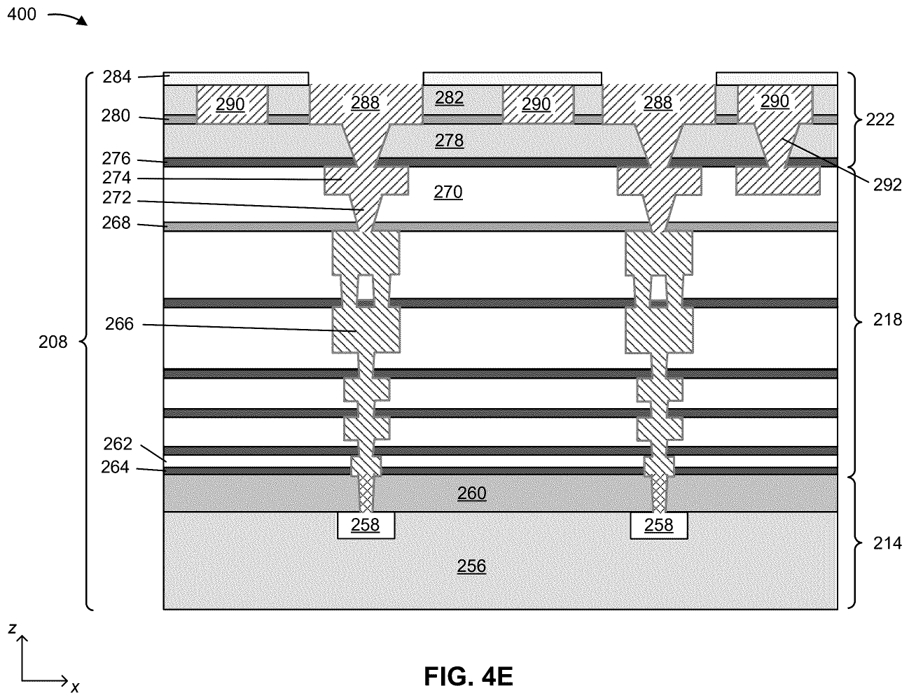

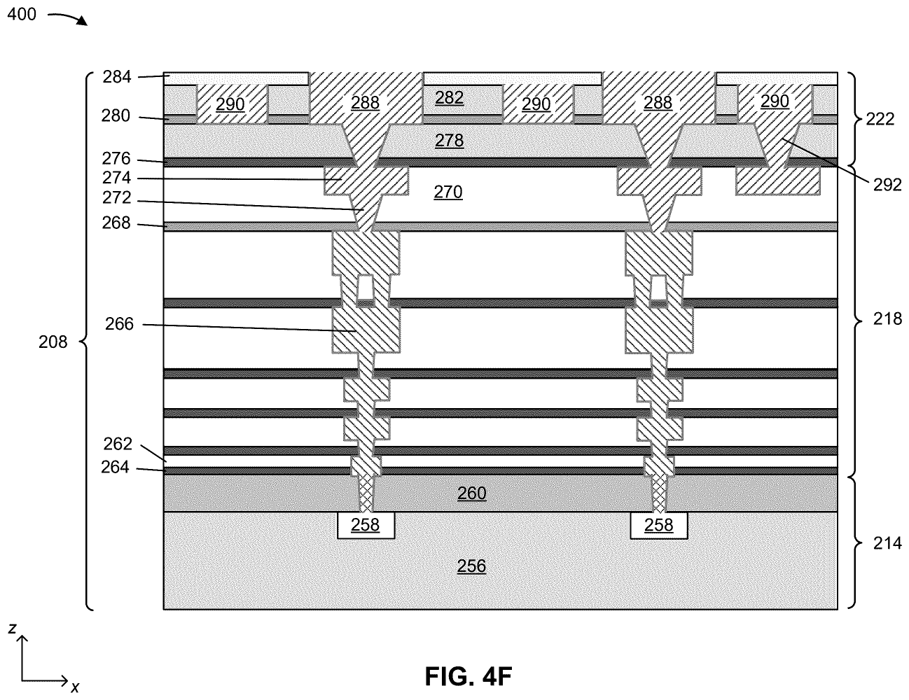

FIGS. 4A-4F are diagrams of an example implementation 400 of forming a semiconductor die 208 described herein. In some implementations, one or more semiconductor processing tools may be used to perform one or more of the semiconductor processing operations described in connection with FIGS. 4A-4F.

Turning to FIG. 4A, similar semiconductor processing operations as described in connection with FIGS. 3A-3H may be performed to form semiconductor devices 258 in and/or on the substrate 256 in the device layer 214 of the semiconductor die 208, to deposit the dielectric layer 260 over and/or on the substrate 256 and over and/or on the semiconductor devices 258, to deposit alternating layers of ESLs 264 and ILD layers 262 of the interconnect structure 218 of the semiconductor die 208, to form the metallization layers 266 in the ILD layers 262 and/or the ESLs 264, to form the ESL 268 and the dielectric layer 270, to form the metal interconnects 272 in the dielectric layers 268 and 270, to form the metal layers 274 on the metal interconnects 272 in the dielectric layer 270, and to form the dielectric layers 276-282 of the bonding structure 222 of the semiconductor die 208.

As shown in FIG. 4B, recesses 402, 404, and 406 are formed in and/or through the dielectric layers 280 and 282 in the bonding structure 222. The recesses 402 and 404 are further formed through the dielectric layers 278 and 276 in the bonding structure 222. The top surfaces of the metal layers 274 are exposed through the recesses 402 in preparation for forming bonding vias 286 on the metal layers 274. Top surfaces of one or more metal layers 274 may also be exposed through the recess 404 in preparation for forming one or more grounding vias 292 on the one or more metal layers 274. The recesses 406 are formed in preparation for forming the shielding grid 290 around the bonding pads 288 of the semiconductor die 208.

In some implementations, a dual damascene process is used to form the recesses 402 and 404. In these implementations, a via portion of the recesses 402 and 404 and trench portions of the recesses 402 and 404 are formed sequentially. For example, a via-first dual damascene process may be performed in which via portions of the recesses 402 and 404 may be formed from a top surface of the dielectric layer 282 through the dielectric layer 282, through the dielectric layer 280, through the dielectric layer 278, and through the dielectric layer 276 to the metal layers 274. Trench portions of the recesses 402 and 404 may be formed such that the trench portions are formed by laterally expanding (e.g., in the x-direction and/or in the y-direction) top sections of the via portions. The recesses 406 may also be formed along with (e.g., at the same time as) the trench portions of the recesses 402 and 404. Alternatively, a trench-first dual damascene procedure, in which the recesses 402 and 404 are formed by forming the trench portion before forming the via portion, may be performed.

A deposition tool may be used to form a photoresist layer on the dielectric layer 282. An exposure tool may be used to expose the photoresist layer to a radiation source to pattern the photoresist layer. A developer tool may be used to develop and remove portions of the photoresist layer to expose the pattern. An etch tool may be used to etch the dielectric layers 276-282 to form the via portions of the recesses 402 and 404. In some implementations, a photoresist removal tool removes the remaining portions of the photoresist layer (e.g., using a chemical stripper and/or another technique).

Subsequently, a deposition tool may be used to form a photoresist layer on the dielectric layer 282. An exposure tool may be used to expose the photoresist layer to a radiation source to pattern the photoresist layer. A developer tool may be used to develop and remove portions of the photoresist layer to expose the pattern. An etch tool may be used to etch the dielectric layers 280 and 282 to form the trench portions of the recesses 402 and 404, as well as the recesses 406. In some implementations, a photoresist removal tool removes the remaining portions of the photoresist layer (e.g., using a chemical stripper and/or another technique).

As shown in FIG. 4C, the bonding vias 286 are formed in the via portion of the recesses 402 such that the bonding vias 286 land on (and are electrically coupled and/or physically coupled with) the metal layers 274. The bonding pads 288 are formed in the trench portion of the recesses 402 on the bonding vias 286. The bonding vias 286 and the bonding pads 288 may each include one or more liner layers 408 and a conductive structure 410. The one or more liner layers 408 may include adhesion layers, barrier layers, and/or another type of liners that are conformally deposited on the sidewalls and/or the bottom surfaces of the recesses 402. Examples of materials for the one or more liner layers 408 include tantalum nitride (TaN), titanium nitride (TiN), ruthenium (Ru), cobalt (Co), and/or ruthenium oxide (RuOₓ), among other examples.

A deposition tool may be used to deposit the one or more liner layers 408 using a PVD technique, an ALD technique, a CVD technique, and/or another suitable deposition technique. A deposition tool and/or a plating tool may be used to deposit the conductive structures 410 of the bonding vias 286 and the bonding pads 288 using a CVD technique, a PVD technique, an ALD technique, an electroplating technique, and/or another suitable deposition technique. In some implementations, a seed layer is first deposited on one or more liner layers 408, and a bonding via 286 and/or a bonding pad 288 is deposited on the seed layer. In some implementations, a planarization tool is used to planarize the bonding pads 288 after the bonding pads 288 are deposited.

As further shown in FIG. 4C, the grounding via 292 is formed in the via portion of the recess 404 such that the grounding via 292 lands on (and are electrically coupled and/or physically coupled with) a metal layer 274. The shielding grid 290 is formed in the trench portion of the recess 404 and in the recesses 406. The grounding via 292 and the shielding grid 290 may each include one or more liner layers 408 and a conductive structure 410. The one or more liner layers 408 may include adhesion layers, barrier layers, and/or another type of liners that are conformally deposited on the sidewalls and/or the bottom surfaces of the recesses 404 and/or 406.

A deposition tool and/or a plating tool may be used to deposit the conductive structures 410 of the grounding via 292 and the shielding grid 290 using a CVD technique, a PVD technique, an ALD technique, an electroplating technique, and/or another suitable deposition technique. In some implementations, a seed layer is first deposited on one or more liner layers 408, and grounding via 292 and/or the shielding grid 290 are deposited on the seed layer. In some implementations, a planarization tool is used to planarize the shielding grid 290 after the shielding grid 290 is deposited.

As shown in FIG. 4D, the bonding dielectric layer 284 is formed over and/or on the dielectric layer 282. The bonding dielectric layer 284 is also formed over and/or on the bonding pads 288 and the shielding grid 290. A deposition tool may be used to deposit the bonding dielectric layer 284 using a PVD technique, an ALD technique, a CVD technique, and/or another suitable deposition technique. In some implementations, the planarization tool is used to planarize the bonding dielectric layer 284 after the bonding dielectric layer 284 is deposited.

As shown in FIG. 4E, portions of the bonding dielectric layer 284 are removed to expose the bonding pads 288 through the bonding dielectric layer 284. In some implementations, a pattern in a photoresist layer is used to etch the bonding dielectric layer 284 to remove the portions of the bonding dielectric layer 284. In these implementations, a deposition tool may be used to form the photoresist layer on the bonding dielectric layer 284. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 284 based on the pattern to remove the portions of the bonding dielectric layer 284. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the bonding dielectric layer 284 based on a pattern.

As shown in FIG. 4F, additional material of the bonding pads 288 is deposited. The additional material may be planarized using a planarization tool such that top surfaces of the bonding pads 288 are co-planar with a top surface of the bonding dielectric layer 284. A deposition tool and/or a plating tool may be used to deposit the additional material of the bonding pads 288 using a CVD technique, a PVD technique, an ALD technique, an electroplating technique, another deposition technique

As indicated above, FIGS. 4A-4F are provided as an example. Other examples may differ from what is described with regard to FIGS. 4A-4F.

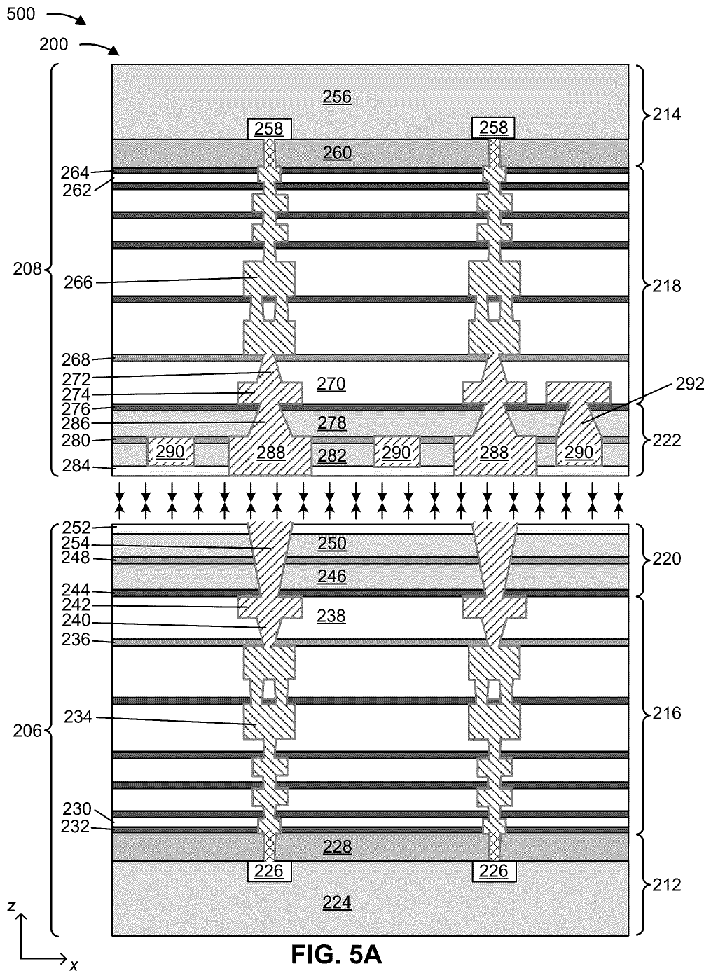

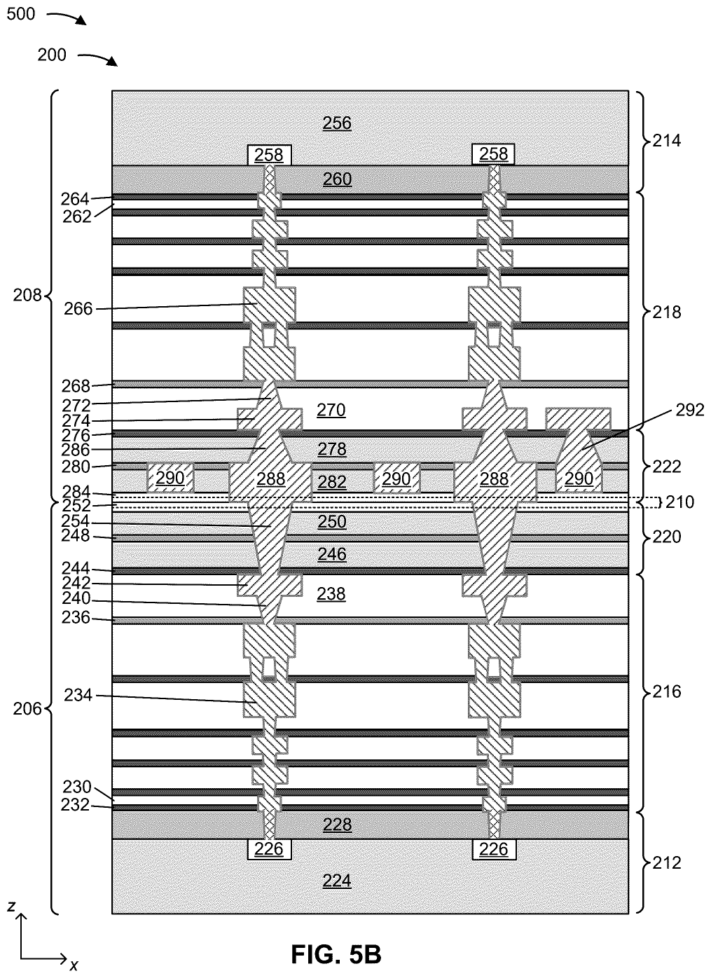

FIGS. 5A and 5B are diagrams of an example implementation 500 of forming a semiconductor device 200 described herein. In particular, the example implementation 500 includes an example of bonding the semiconductor die 206 and the semiconductor die 208 to form the semiconductor device 200. In some implementations, one or more semiconductor processing tools may be used to perform one or more of the semiconductor processing operations described in connection with FIGS. 5A and 5B.

As shown in 5A and 5B, a bonding operation is performed to bond the semiconductor die 206 and the semiconductor die 208 at the bonding interface 210 such that the semiconductor die 206 and the semiconductor die 208 are vertically arranged or stacked. The semiconductor die 206 and the semiconductor die 208 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 206 and the semiconductor die 208 at the bonding interface 210. The bonding operation may include forming a direct bond between the semiconductor die 206 and the semiconductor die 208 through the physical connection of the bonding vias 254 of the semiconductor die 206 and the bonding pads 288 of the semiconductor die 208, and the physical connection of the bonding dielectric layer 252 of the semiconductor die 206 and bonding dielectric layer 284 of the semiconductor die 208. At the bonding interface 210, a direct metal-to-metal bond is formed between the bonding vias 254 and the bonding pads 288, and a direct dielectric-to-dielectric bond is formed between the bonding dielectric layers 252 and 284. Accordingly, the bonding operation may be referred to as a “hybrid bonding” operation in that different types of material-to-material bonds are formed in the bonding operation.

In some implementations, the semiconductor die 206 and the semiconductor die 208 are bonded as part of bonding the semiconductor wafer 202 and the semiconductor wafer 204 in the bonding operation. Accordingly, the semiconductor device 200 (and other semiconductor devices 200) may be diced or cut from the bonded semiconductor wafer 202 and the semiconductor wafer 204 and packaged.

To bond the semiconductor dies 206 and 208, a bonding tool may be used to align the semiconductor die 206 and 208 such that a bonding surface (e.g., a bonding surface 294) of a bonding via 254 is located on and/or within a perimeter of a bonding surface (e.g., a bonding surface 296) of a bonding pad 288. In other words, the bonding tool may be used to align the semiconductor dies 206 and 208 such that a perimeter of the bonding surface of the bonding via 254 and the perimeter of the bonding surface of the bonding pad 288 partially overlap. The perimeters of the bonding surfaces of the bonding via 254 and the bonding pad 288 do not fully overlap because of the lesser size of the bonding surface of the bonding via 254 than the size of the bonding surface of the bonding pad 288. The lesser size of the bonding surface of the bonding via 254 provides greater flexibility in achieving a satisfactory overlay percentage between the bonding via 254 and the bonding pad 288 in that sufficient bonding quality may be achieved if there is a threshold amount of overlap between the bonding surface of the bonding via 254 and the perimeter of the bonding surface of the bonding pad 288. This provides a greater flexibility and a larger process window for aligning the bonding vias 254 of the semiconductor die 208 and the bonding pads 288 of the semiconductor die 288 for bonding, which may decrease the rate and/or likelihood of defect formation for bonding semiconductor dies on the semiconductor wafers 202 and 204 and/or may increase bonding yield for bonding semiconductor dies on the semiconductor wafers 202 and 204.

As indicated above, FIGS. 5A and 5B are provided as an example. Other examples may differ from what is described with regard to FIGS. 5A and 5B.

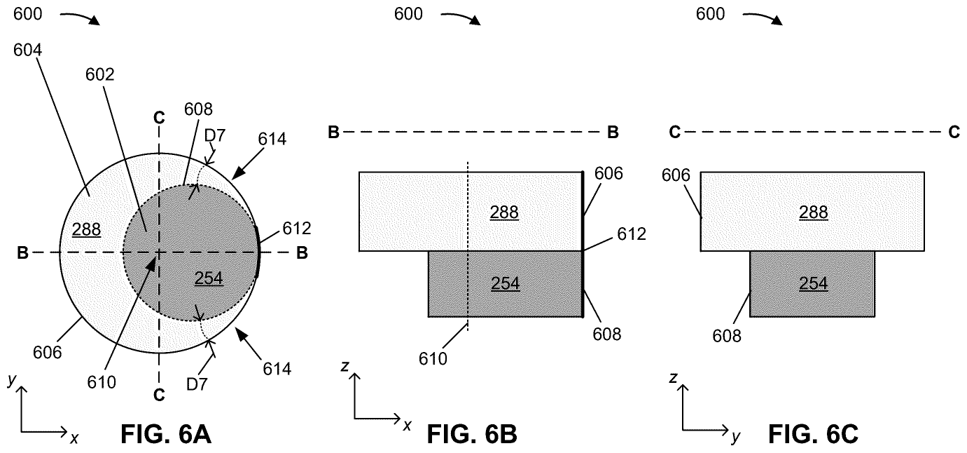

FIGS. 6A-6C are diagrams of an example implementation 600 of a bonding via 254 of a semiconductor die 206 and a bonding pad 288 of a semiconductor die 208 described herein. FIG. 6A is a top view of the bonding via 254 and the bonding pad 288. FIG. 6B is a cross-section view in the x-direction along the line B-B in FIG. 6A. FIG. 6C is a cross-section view in the y-direction along the line C-C in FIG. 6A.

As shown in FIG. 6A, the bonding via 254 and the bonding pad 288 are bonded at a bonding surface 602 of the bonding via 254 and a bonding surface 604 of the bonding pad 288. The bonding surface 604 is bonded with an entirety of the surface area of the bonding surface 602. Because of the lesser size of the bonding surface 602, the bonding surface 602 is bonded with less than an entirety of the surface area of the bonding surface 604. The bonding surface 602 has a circle top view shape in the top view of the bonding via 254, and the bonding surface 604 also has a circle top view shape in the top view of the bonding pad 288.

The bonding via 254 and/or the bond pad 288 are aligned in the x-y plane such that the bonding surface 602 is located within a perimeter (e.g., a circumference) 606 of the bonding surface 604. Thus, a perimeter (e.g., a circumference) 608 of the bonding surface 602 is less than the perimeter 606 of the bonding pad 288. Moreover, the bonding via 254 and/or the bond pad 288 are aligned in the x-y plane such that the perimeter 608 of the bonding surface 602 overlaps with a portion of the perimeter 606 of the bonding surface 604. As shown in FIGS. 6A and 6B, the bonding surface 602 is offset relative to a center 610 of the bonding surface 604 such that an overlapped section 612 between the perimeter 608 and the perimeter 606 occurs. Additionally and/or alternatively, and as shown in FIG. 6A, portions 614 of the perimeter 608 of the bonding surface 602 may be located within a distance D7 that satisfies a distance threshold. The distance threshold may be included in a range of approximately 9 nanometers to approximately 10 nanometers. The distance D7 of the portions 614 satisfying the distance threshold enables sufficient bond strength to be achieved between the bonding via 254 and the bonding pad 288. However, other values for the range are within the scope of the present disclosure.

The bonding surface 602 of the bonding via 254 and/or the bonding surface 604 of the bonding pad 288 may be sized such that the overlapped section(s) 612 and/or the portion(s) 614 that satisfy the distance threshold cover approximately 40% to approximately 90% of the perimeter 608 of the bonding surface 602 and/or approximately 40% to approximately 90% of the perimeter 606 of the bonding surface 604. The overlapped section(s) 612 and/or the portion(s) 614 that satisfy the distance threshold being approximately 40% to approximately 90% of the perimeter 608 of the bonding surface 602 and/or being approximately 40% to approximately 90% of the perimeter 606 of the bonding surface 604 provides sufficient bond strength between the bonding via 254 and the bonding pad 288, which reduces the likelihood of bonding defects in the semiconductor device 200 and/or increases the yield of semiconductor device 200. Additionally and/or alternatively, overlapped section(s) 612 and/or the portion(s) 614 that satisfy the distance threshold being approximately 40% to approximately 90% of the perimeter 608 of the bonding surface 602 and/or being approximately 40% to approximately 90% of the perimeter 606 of the bonding surface 604 enables the bonding vias 254 to be spaced sufficiently far apart to achieve a low amount of electrical coupling between the bonding vias 254. However, other values for these ranges are within the scope of the present disclosure.

As indicated above, FIGS. 6A-6C are provided as an example. Other examples may differ from what is described with regard to FIGS. 6A-6C.

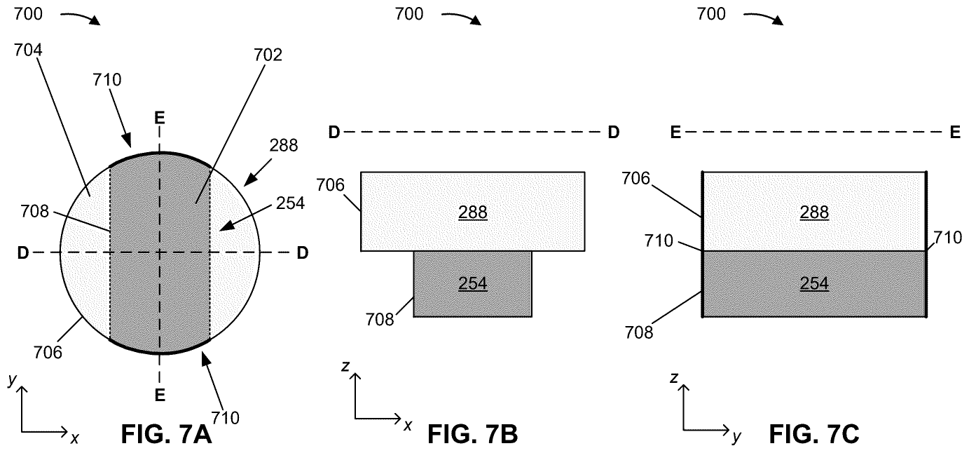

FIGS. 7A-7C are diagrams of an example implementation 700 of a bonding via 254 of a semiconductor die 206 and a bonding pad 288 of a semiconductor die 208 described herein. FIG. 7A is a top view of the bonding via 254 and the bonding pad 288. FIG. 7B is a cross-section view in the x-direction along the line D-D in FIG. 7A. FIG. 7C is a cross-section view in the y-direction along the line E-E in FIG. 7A.

As shown in FIG. 7A, the bonding via 254 and the bonding pad 288 are bonded at a bonding surface 702 of the bonding via 254 and a bonding surface 704 of the bonding pad 288. The bonding surface 704 is bonded with an entirety of the surface area of the bonding surface 702. Because of the lesser size of the bonding surface 702, the bonding surface 702 is bonded with less than an entirety of the surface area of the bonding surface 704. The bonding surface 702 has an obround (or stadium) top view shape in the top view of the bonding via 254. In particular, the bonding surface 702 includes rounded ends (e.g., semicircular ends) connected by approximately parallel sides that are tangential to the endpoints of the rounded ends. In other words, the bonding surface 702 includes a rectangular top vie shape with rounded ends. The bonding surface 704 has a circle top view shape in the top view of the bonding pad 288.

The bonding via 254 and/or the bond pad 288 are aligned in the x-y plane such that the bonding surface 702 is located within a perimeter (e.g., a circumference) 706 of the bonding surface 704. Thus, a perimeter 708 of the bonding surface 702 of the bonding via 254 is less than the perimeter 706 of the bonding surface 704 of the bonding pad 288. Moreover, and as shown in FIGS. 7A and 7C, the bonding via 254 and/or the bond pad 288 are aligned in the x-y plane such that the perimeter 708 of the bonding surface 702 overlaps with a portion of the perimeter 706 of the bonding surface 704. The rounded ends of the bonding surface 702 overlap portions of the perimeter 706 of the bonding surface 704 such that overlapped sections 710 between the perimeter 708 and the perimeter 706 occur. The bonding surface 702 of the bonding via 254 and/or the bonding surface 704 of the bonding pad 288 may be sized such that the overlapped section(s) 710 cover approximately 40% to approximately 90% of the perimeter 708 of the bonding surface 702 and/or approximately 40% to approximately 90% of the perimeter 706 of the bonding surface 704.

As indicated above, FIGS. 7A-7C are provided as an example. Other examples may differ from what is described with regard to FIGS. 7A-7C.

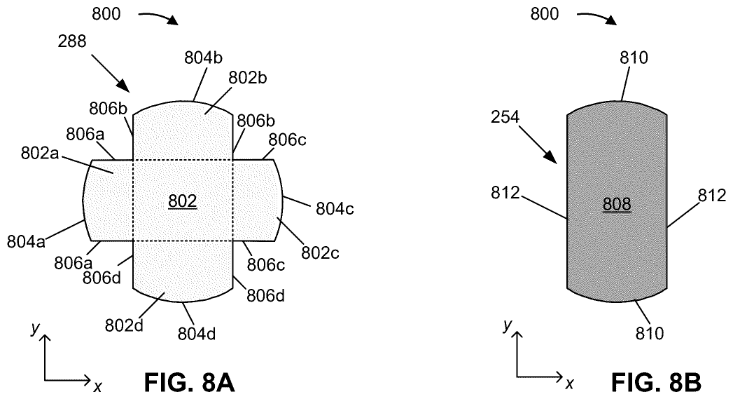

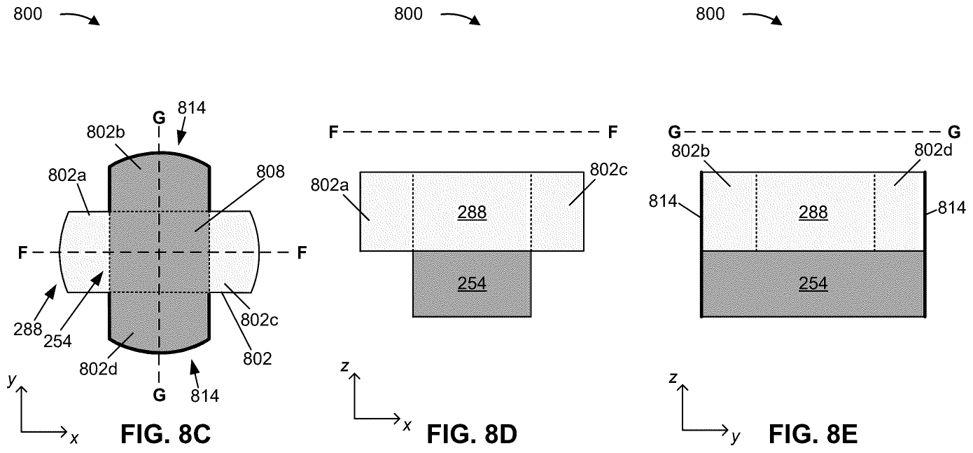

FIGS. 8A-8E are diagrams of an example implementation 800 of a bonding via 254 of a semiconductor die 206 and a bonding pad 288 of a semiconductor die 208 described herein. FIG. 8A is a top view of the bonding pad 288. FIG. 8B is a top view ofs the bonding via 254. FIG. 8C is a top view of the bonding via 254 bonded with the bonding pad 288. FIG. 8D is a cross-section view in the x-direction along the line F-F in FIG. 8C. FIG. 8E is a cross-section view in the y-direction along the line G-G in FIG. 8C.

As shown in FIG. 8A, the bonding pad 288 has a bonding surface 802 that has a cruciate (or cross-shaped) top view shape. The bonding surface 802 includes a plurality of segments 802a-802d extending from a central region of the bonding surface 802 in a cross pattern. One or more of the segments 802a-802d may have rounded ends. For example, the segment 802a may have a rounded end 804a, the segment 802b may have a rounded end 804b, the segment 802c may have a rounded end 804c, and/or the segment 802d may have a rounded end 804d. The segment 802a may further include approximately parallel sidewalls 806a that are tangential to endpoints of the rounded end 804a. The segment 802b may further include approximately parallel sidewalls 806b that are tangential to endpoints of the rounded end 804b. The segment 802c may further include approximately parallel sidewalls 806c that are tangential to endpoints of the rounded end 804c. The segment 802d may further include approximately parallel sidewalls 806d that are tangential to endpoints of the rounded end 804d. The rounded ends 802a-802d and the approximately parallel sidewalls 806a-806d correspond to a perimeter of the bonding surface 802 of the bonding pad 288.

As shown in FIG. 8B, the bonding via 254 has a bonding surface 808 that has an obround (or stadium) top view shape in the top view of the bonding via 254. In particular, the bonding surface 808 includes rounded ends (e.g., semicircular ends) 810 connected by approximately parallel sidewalls 812 that are tangential to the endpoints of the rounded ends 810. The rounded ends 810 and the approximately parallel sidewalls 812 correspond to a perimeter of the bonding surface 808.

As shown in FIG. 8C, the bonding via 254 and the bonding pad 288 are bonded at the bonding surface 802 of the bonding pad 288 and the bonding surface 808 of the bonding via 254. The bonding surface 802 is bonded with an entirety of the surface area of the bonding surface 808. Because of the lesser size of the bonding surface 808, the bonding surface 808 is bonded with less than an entirety of the surface area of the bonding surface 802.

The bonding via 254 and/or the bond pad 288 are aligned in the x-y plane such that the bonding surface 808 is located within the perimeter of the bonding surface 802. Thus, a perimeter of the bonding surface 808 of the bonding via 254 is less than the perimeter of the bonding surface 802 of the bonding pad 288. Moreover, and as shown in FIGS. 8C and 8E, the bonding via 254 and/or the bond pad 288 are aligned in the x-y plane such that the perimeter of the bonding surface 808 overlaps with a portion of the perimeter of the bonding surface 802. The rounded ends 810 and portions of the approximately parallel sidewalls 812 of the bonding surface 808 overlap with rounded ends and approximately parallel sidewalls of one or more segments 802a-802d of the bonding surface 802 such that overlapped sections 814 between the perimeter of the bonding surface 802 and the perimeter of the bonding surface 808 occur. For example, the rounded ends 810 and portions of the approximately parallel sidewalls 812 of the bonding surface 808 may overlap with the rounded end 804b and the approximately parallel sidewalls 806b of the segment 802b. As another example, the rounded ends 810 and portions of the approximately parallel sidewalls 812 of the bonding surface 808 may overlap with the rounded end 804d and the approximately parallel sidewalls 806d of the segment 802d. The bonding surface 808 of the bonding via 254 and/or the bonding surface 802 of the bonding pad 288 may be sized such that the overlapped section(s) 814 cover approximately 40% to approximately 90% of the perimeter of the bonding surface 802 and/or approximately 40% to approximately 90% of the perimeter of the bonding surface 808.

As indicated above, FIGS. 8A-8E are provided as an example. Other examples may differ from what is described with regard to FIGS. 8A-8E.

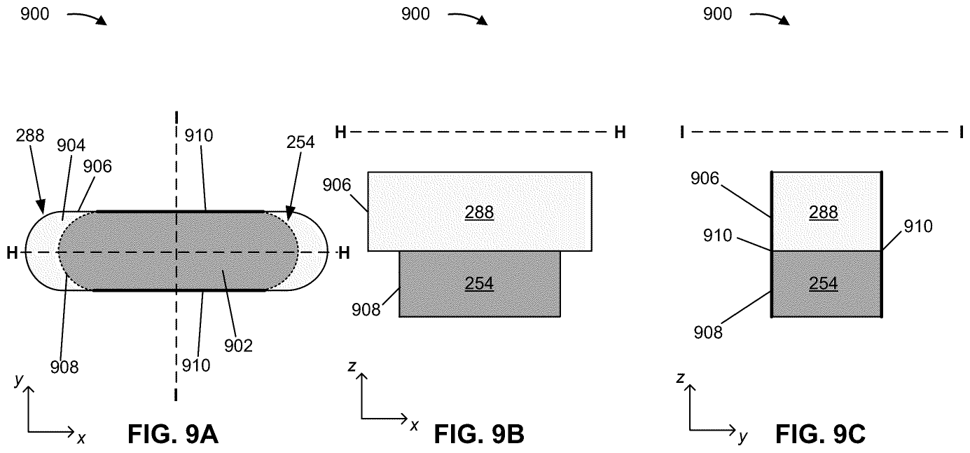

FIGS. 9A-9C are diagrams of an example implementation 900 of a bonding via 254 of a semiconductor die 206 and a bonding pad 288 of a semiconductor die 208 described herein. FIG. 9A is a top view of the bonding via 254 and the bonding pad 288. FIG. 9B is a cross-section view in the x-direction along the line H-H in FIG. 9A. FIG. 9C is a cross-section view in the y-direction along the line I-I in FIG. 9A.

As shown in FIG. 9A, the bonding via 254 and the bonding pad 288 are bonded at a bonding surface 902 of the bonding via 254 and a bonding surface 904 of the bonding pad 288. The bonding surface 904 is bonded with an entirety of the surface area of the bonding surface 902. Because of the lesser size of the bonding surface 902, the bonding surface 902 is bonded with less than an entirety of the surface area of the bonding surface 904. The bonding surface 902 has an obround (or stadium) top view shape in the top view of the bonding via 254. In particular, the bonding surface 902 includes rounded ends (e.g., semicircular ends) connected by approximately parallel sides that are tangential to the endpoints of the rounded ends. The bonding surface 904 also has an obround (or stadium) top view shape in the top view of the bonding pad 288. In particular, the bonding surface 904 includes rounded ends (e.g., semicircular ends) connected by approximately parallel sides that are tangential to the endpoints of the rounded ends. A top view length of the obround top view shape of the bonding surface 902 is less than a top view length of the obround top view shape of the bonding surface 904.

The bonding via 254 and/or the bond pad 288 are aligned in the x-y plane such that the bonding surface 902 is located within a perimeter (e.g., a circumference) 906 of the bonding surface 904. Thus, a perimeter 908 of the bonding surface 902 of the bonding via 254 is less than the perimeter 906 of the bonding surface 904 of the bonding pad 288. Moreover, and as shown in FIGS. 9A and 9C, the bonding via 254 and/or the bond pad 288 are aligned in the x-y plane such that the perimeter 908 of the bonding surface 902 overlaps with a portion of the perimeter 906 of the bonding surface 904. The approximately parallel sidewalls of the bonding surface 902 overlap portions of the approximately parallel sidewalls of the bonding surface 904 such that overlapped sections 910 between the perimeter 908 and the perimeter 906 occur. The bonding surface 902 of the bonding via 254 and/or the bonding surface 904 of the bonding pad 288 may be sized such that the overlapped section(s) 910 cover approximately 40% to approximately 90% of the perimeter 908 of the bonding surface 902 and/or approximately 40% to approximately 90% of the perimeter 906 of the bonding surface 904.

As indicated above, FIGS. 9A-9C are provided as an example. Other examples may differ from what is described with regard to FIGS. 9A-9C.

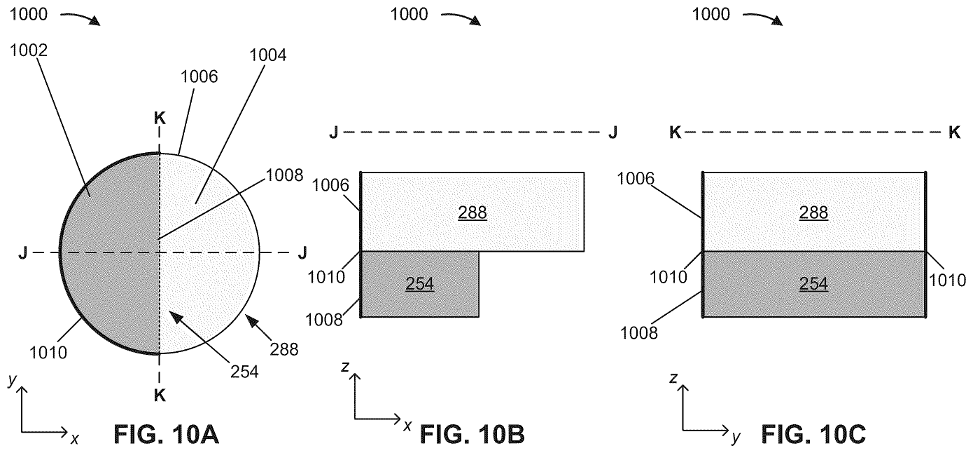

FIGS. 10A-10C are diagrams of an example implementation 1000 of a bonding via 254 of a semiconductor die 206 and a bonding pad 288 of a semiconductor die 208 described herein. FIG. 10A is a top view of the bonding via 254 and the bonding pad 288. FIG. 10B is a cross-section view in the x-direction along the line J-J in FIG. 10A. FIG. 10C is a cross-section view in the y-direction along the line K-K in FIG. 10A.

As shown in FIG. 10A, the bonding via 254 and the bonding pad 288 are bonded at a bonding surface 1002 of the bonding via 254 and a bonding surface 1004 of the bonding pad 288. The bonding surface 1004 is bonded with an entirety of the surface area of the bonding surface 1002. Because of the lesser size of the bonding surface 1002, the bonding surface 1002 is bonded with less than an entirety of the surface area of the bonding surface 1004. The bonding surface 1002 has a semicircular top view shape in the top view of the bonding via 254. The bonding surface 1004 also has a circle top view shape in the top view of the bonding pad 288.

The bonding via 254 and/or the bond pad 288 are aligned in the x-y plane such that the bonding surface 1002 is located within a perimeter (e.g., a circumference) 1006 of the bonding surface 1004. Thus, a perimeter 1008 of the bonding surface 1002 of the bonding via 254 is less than the perimeter 1006 of the bonding surface 1004 of the bonding pad 288. Moreover, and as shown in FIGS. 10A-10C, the bonding via 254 and/or the bond pad 288 are aligned in the x-y plane such that the perimeter 1008 of the bonding surface 1002 overlaps with a portion of the perimeter 1006 of the bonding surface 1004. The round portion of the bonding surface 1002 overlaps with a portion of the perimeter 1006 of the bonding surface 1004 such that an overlapped section 1010 between the perimeter 1006 and the perimeter 1008 occurs. The bonding surface 1002 of the bonding via 254 and/or the bonding surface 1004 of the bonding pad 288 may be sized such that the overlapped section(s) 1010 cover approximately 40% to approximately 90% of the perimeter 1008 of the bonding surface 1002 and/or approximately 40% to approximately 90% of the perimeter 1006 of the bonding surface 1004.

As indicated above, FIGS. 10A-10C are provided as an example. Other examples may differ from what is described with regard to FIGS. 10A-10C. Moreover, top view shapes and/or sizes other than those illustrated and described in connection with FIGS. 6A-6C, 7A-7C, 8A-8E, 9A-9C, and 10A-10C may also be used. The bonding surfaces of the bonding vias 254 and/or the bonding surfaces of the bonding pads 288 may be shaped and/or sized to achieve a particular amount of overlap between the perimeters of the bonding vias 254 and the perimeters of the bonding pads 288 to achieve sufficient bond strength while providing sufficient spacing between the bonding vias 254 to achieve a low amount of coupling between the bonding vias 254 without the inclusion of an additional shielding grid around the bonding vias 254. Additionally and/or alternatively, a semiconductor device 200 may include a combination of two or more example implementations of bonding vias 254 and/or a combination of two or more example implementations of bonding pads 288 illustrated and described in connection with FIGS. 6A-6C, 7A-7C, 8A-8E, 9A-9C, and/or 10A-10C, among other examples.

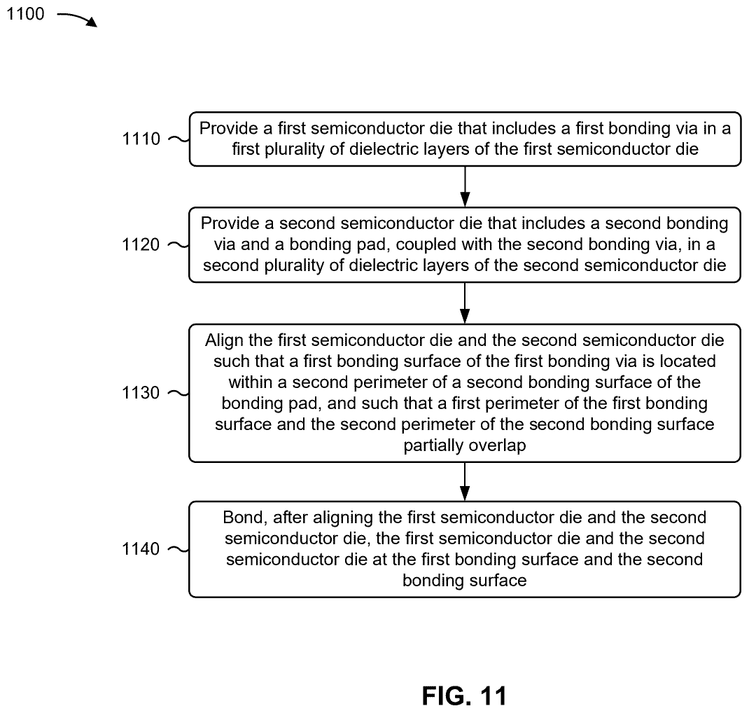

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a plating tool, a planarization tool, an ion implantation tool, and/or a wafer/die transport tool, among other examples.

As shown in FIG. 11, process 1100 may include providing a first semiconductor die that includes a first bonding via in a first plurality of dielectric layers of the first semiconductor die (block 1110). For example, one or more semiconductor processing tools may be used to provide a semiconductor die 206 that includes a bonding via 254 in a plurality of dielectric layers 244-252 of the semiconductor die 206, as described herein.

As further shown in FIG. 11, process 1100 may include providing a second semiconductor die that includes a second bonding via and a bonding pad coupled with the second bonding via in a second plurality of dielectric layers of the second semiconductor die (block 1120). For example, one or more semiconductor processing tools may be used to provide a semiconductor die 208 that includes a bonding via 286 and a bonding pad 288 coupled with the bonding via 286 in a plurality of dielectric layers 276-284 of the semiconductor die 208, as described herein.

As further shown in FIG. 11, process 1100 may include aligning the first semiconductor die and the second semiconductor die such that a first bonding surface of the first bonding via is located within a second perimeter of a second bonding surface of the bonding pad, and such that a first perimeter of the first bonding surface and the second perimeter of the second bonding surface partially overlap (block 1130). For example, one or more semiconductor processing tools may be used to align the semiconductor die 206 and the semiconductor die 208 such that a first bonding surface of the bonding via 254 is located within a second perimeter of a second bonding surface of the bonding pad 288, and such that a first perimeter of the first bonding surface and the second perimeter of the second bonding surface partially overlap, as described herein.

As further shown in FIG. 11, process 1100 may include bonding, after aligning the first semiconductor die and the second semiconductor die, the first semiconductor die and the second semiconductor die at the first bonding surface and the second bonding surface (block 1140). For example, one or more semiconductor processing tools may be used to bond, after aligning the semiconductor die 206 and the semiconductor die 208, the semiconductor die 206 and the semiconductor die 208 at the first bonding surface and the second bonding surface, as described herein.

Process 1100 may include additional implementations, such as any single implementation or any combination of implementations described below and/or in connection with one or more other processes described elsewhere herein.

In a first implementation, process 1100 includes forming the second bonding via, forming the bonding pad on the second bonding via, and forming a shielding grid 290, where the shielding grid 290 surrounds the bonding pad.

In a second implementation, alone or in combination with the first implementation, forming the bonding pad and forming the shielding grid include depositing the bonding pad and depositing the shielding grid in a same deposition operation.

In a third implementation, alone or in combination with one or more of the first and second implementations, forming the first bonding via includes forming the first bonding via to have a semicircular top view shape, and forming the bonding pad includes forming the bonding pad to have a circle top view shape.

In a fourth implementation, alone or in combination with one or more of the first through third implementations, forming the first bonding via includes forming the first bonding via to have an obround top view shape, and forming the bonding pad includes forming the bonding pad to have at least one of another obround top view shape, a circle top view shape, or a cruciate top view shape.

In a fifth implementation, alone or in combination with one or more of the first through fourth implementations, forming the first bonding via includes forming the first bonding via such that a first surface area of the first bonding surface is less than a second surface of the second bonding surface of the bonding pad. Thus, the bonding surface area of the bonding pad is greater than the bonding surface area of the first bonding via.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a semiconductor device is formed by bonding a first semiconductor die and a semiconductor die by bonding bonding pads in the first semiconductor die with bonding vias in the second semiconductor die, and by bonding dielectric layers in the first semiconductor die and in the second semiconductor die. The bonding vias of the second semiconductor die may have sizes and/or shapes that are different from the sizes and/or shapes of the bonding pads of the first semiconductor die. For example, the bonding vias of the second semiconductor die may have a width that is less than the width of the bonding pads of the first semiconductor die. Omitting bonding pads from the second semiconductor device, and instead using the bonding vias to bond the first and second semiconductor dies, provides a greater amount of spacing between the bonding vias of the second semiconductor die in that the bonding vias have lesser widths than bonding pads. This enables a greater amount of dielectric material of the dielectric layers of the second semiconductor device to be placed between the bonding vias without (or with minimally) increasing the lateral size of the second semiconductor die. The increased spacing between the bonding vias of the second semiconductor die reduces electrical coupling between the bonding vias of the second semiconductor die without the use of another shielding grid in the second semiconductor die. Thus, the increased spacing between the bonding vias of the second semiconductor die enables a less complex manufacturing process to be used to achieve the reduced electrical coupling between the bonding vias of the second semiconductor die.

As described in greater detail above, some implementations described herein provide a semiconductor device. The semiconductor device includes a first semiconductor die. The first semiconductor die includes a first bonding structure. The first bonding structure includes a first plurality of dielectric layers and a first bonding via included in the first plurality of dielectric layers. The semiconductor device includes a second semiconductor die. The second semiconductor die includes a second bonding structure. The second bonding structure includes a second plurality of dielectric layers, a second bonding via included in the second plurality of dielectric layers, and a bonding pad included in the second plurality of dielectric layers. The first semiconductor die and the second semiconductor die are bonded at a first bonding surface of the first bonding via and a second bonding surface of the bonding pad. An entirety of the first bonding surface is bonded with the second bonding surface, and less than an entirety of the second bonding surface is bonded with the first bonding surface.

As described in greater detail above, some implementations described herein provide a semiconductor device. The semiconductor device includes a first semiconductor die. The first semiconductor die includes a first device layer and a first interconnect structure above the first device layer. The first interconnect structure includes a first metal layer. The first interconnect structure includes a first bonding structure above the first interconnect structure. The first bonding structure includes a first plurality of dielectric layers and a first bonding via included in the first plurality of dielectric layers, where the first bonding via is above and coupled with the first metal layer. The semiconductor device includes a second semiconductor die. The second semiconductor die includes a second device layer. The second semiconductor die includes a second interconnect structure below the second device layer. The second interconnect structure includes a second metal layer. The second semiconductor die includes a second bonding structure below the second interconnect structure. The second bonding structure includes a second plurality of dielectric layers and a second bonding via included in the second plurality of dielectric layers, where the second bonding via is coupled with the second metal layer. The second bonding structure includes a bonding pad included in the second plurality of dielectric layers. The bonding pad is below and coupled with the second bonding via. The first semiconductor die and the second semiconductor die are bonded at the first bonding via and the bonding pad. A bonding surface area of the bonding pad is greater than a bonding surface area of the first bonding via.

As described in greater detail above, some implementations described herein provide a method. The method includes providing a first semiconductor die that includes a first bonding via in a first plurality of dielectric layers of the first semiconductor die. The method includes providing a second semiconductor die that includes a second bonding via and a bonding pad coupled with the second bonding via in a second plurality of dielectric layers of the second semiconductor die. The method includes aligning the first semiconductor die and the second semiconductor die such that a first bonding surface of the first bonding via is located within a second perimeter of a second bonding surface of the bonding pad, and such that a first perimeter of the first bonding surface and the second perimeter of the second bonding surface partially overlap. The method includes bonding, after aligning the first semiconductor die and the second semiconductor die, the first semiconductor die and the second semiconductor die at the first bonding surface and the second bonding surface.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more first dielectric layers in a first bonding structure of a first semiconductor die;
forming a bonding via in the one or more first dielectric layers;
forming one or more second dielectric layers in a second bonding structure of a second semiconductor die;
forming a bonding pad in the one or more second dielectric layers; and
bonding a first bonding surface of the bonding via and a second bonding surface of the bonding pad to bond the first semiconductor die and the second semiconductor die together,
wherein an entirety of the first bonding surface is bonded with the second bonding surface, and
wherein less than an entirety of the second bonding surface is bonded with the first bonding surface.

2. The method of claim 1, wherein the first bonding surface and the second bonding surface have different top view shapes.

3. The method of claim 2, wherein the first bonding surface has a rectangular top view shape and the second bonding surface has a circle top view shape.

4. The method of claim 2, wherein the first bonding surface has an obround top view shape and the second bonding surface as a cruciate top view shape.

5. The method of claim 2, wherein the first bonding surface has a first obround top view shape and the second bonding surface has a second obround top view shape.

6. The method of claim 1, wherein the bonding via extends through a first quantity of the one or more first dielectric layers,
wherein the bonding pad extends through a second quantity of the one or more second dielectric layers, and
wherein the first quantity and the second quantity are different quantities.

7. The method of claim 6, wherein the first quantity is greater than the second quantity.

8. A method, comprising:
forming one or more first dielectric layers in a first bonding structure of a first semiconductor die;
forming a bonding via in the one or more first dielectric layers;
forming one or more second dielectric layers in a second bonding structure of a second semiconductor die;
forming a bonding pad in the one or more second dielectric layers; and
bonding a first bonding surface of the bonding via and a second bonding surface of the bonding pad to bond the first semiconductor die and the second semiconductor die together,
wherein a bonding surface area of the bonding pad and a bonding surface area of the bonding via are different bonding surface areas.

9. The method of claim 8, wherein the bonding surface area of the bonding pad is greater than the bonding surface area of the bonding via.

10. The method of claim 8, wherein forming the bonding via comprises:
etching the one or more first dielectric layers to form a recess through the one or more first dielectric layers; and
depositing material of the bonding via in the recess.

11. The method of claim 8, wherein forming the bonding pad comprises:
etching the one or more second dielectric layers and one or more third dielectric layers in the second bonding structure to form a dual damascene recess in the one or more second dielectric layers and the one or more third dielectric layers; and
depositing material of the bonding pad in the dual damascene recess.

12. The method of claim 11, further comprising:
depositing material of another bonding via in a via portion of the dual damascene recess such that the other bonding via extends through the one or more third dielectric layers.

13. The method of claim 11, wherein etching the one or more second dielectric layers and the one or more third dielectric layers in the second bonding structure to form the dual damascene recess comprises:
etching the one or more second dielectric layers to form a trench portion of the dual damascene recess; and
etching the one or more third dielectric layers to form a via portion of the dual damascene recess after forming the trench portion.

14. The method of claim 11, wherein etching the one or more second dielectric layers and the one or more third dielectric layers in the second bonding structure to form the dual damascene recess comprises:
etching the one or more second dielectric layers and the one or more third dielectric layers to form a via portion of the dual damascene recess; and
etching the one or more second dielectric layers to form a trench portion of the dual damascene recess after forming the via portion.

15. A method, comprising:
forming one or more first dielectric layers in a first bonding structure of a first semiconductor die;
forming a bonding via in the one or more first dielectric layers;
forming one or more second dielectric layers in a second bonding structure of a second semiconductor die;
forming a bonding pad in the one or more second dielectric layers;
forming a shielding grid in the one or more second dielectric layers; and
bonding a first bonding surface of the bonding via and a second bonding surface of the bonding pad to bond the first semiconductor die and the second semiconductor die together,
wherein a third bonding surface of the shielding grid is in contact with a dielectric layer of the one or more first dielectric layers.

16. The method of claim 15, wherein forming the bonding pad and forming the shielding grid comprise:
depositing material of the bonding pad and material of the shielding grid in a same deposition operation.

17. The method of claim 15, wherein forming the shielding grid comprises:
forming the shielding grid such that the shielding grid laterally surrounds the bonding pad.

18. The method of claim 15, wherein forming the bonding pad and forming the shielding grid comprise:
etching the one or more second dielectric layers in a same etch operation to form recesses for the bonding pad and for the shielding grid.

19. The method of claim 18, further comprising:
etching one or more third dielectric layers under the one or more second dielectric layers to form the recesses through the one or more second dielectric layers and through the one or more third dielectric layers; and
depositing material of other bonding vias in the recesses.

20. The method of claim 15, wherein forming the bonding pad comprises:
forming the bonding pad on a first bonding via of the other bonding vias, and
wherein forming the shielding grid comprises:
forming the shielding grid on a second bonding via of the other bonding vias.
